(19) United States
(12) Patent Application Publication
(10) Pub. No.: US 2026/0136520 A1
(43) Pub. Date: May 14, 2026

(54) SEMICONDUCTOR DEVICE

(71) Applicant: Samsung Electronics Co., Ltd., Suwon-si (KR)

(72) Inventors: Min Jeong CHOI, Suwon-si (KR); Hyung Ki CHO, Suwon-si (KR); Sung Won YOO, Suwon-si (KR)

(21) Appl. No.: 19/327,488

(22) Filed: Sep. 12, 2025

(30) Foreign Application Priority Data
Nov. 14, 2024 (KR) 10-2024-0161972

(51) Int. Cl. H10B 12/00

(52) U.S. Cl. CPC H10B 12/00

(57) ABSTRACT

A semiconductor device of which the degree of integration and electrical characteristics are improved. The semiconductor device includes a first lower conductive line, a first channel pattern disposed on the first lower conductive line, a storage node pattern disposed on the first channel pattern and in contact with the first channel pattern, a second lower conductive line disposed between the storage node pattern and the first channel pattern, a first upper conductive line disposed on the storage node pattern, a second channel pattern disposed between the first upper conductive line and the storage node pattern and connected to the first upper conductive line, an upper gate insulating pattern disposed between the second channel pattern and the storage node pattern and a second upper conductive line disposed on the second channel pattern, and connected to the second channel pattern.

### CROSS-REFERENCE TO RELATED APPLICATION

This application claims priority from Korean Patent Application No. 10-2024-0161972 filed on Nov. 14, 2024, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor device, and more particularly, to a semiconductor device including a vertical channel transistor (VCT).

### 2. Description of the Related Art

In order to meet high performance and a low price demanded by consumers, it has been required to increase the degree of integration of semiconductor memory devices. Since the degree of integration of the semiconductor memory device is an important factor in determining a price of a product, the semiconductor memory device is particularly required to have an increased degree of integration.

In a case of a two-dimensional or planar semiconductor memory device, the degree of integration of the semiconductor memory device is mainly determined by an area occupied by a unit memory cell, and thus, is greatly affected by a level of a fine pattern forming technology. However, since ultra-expensive equipment is required in order to make patterns fine, the degree of integration of the two-dimensional semiconductor memory device has increased, but is still restrictive. Accordingly, semiconductor memory devices including a vertical channel transistor in which a channel extends in a vertical direction have been proposed.

### SUMMARY

Aspects of the present disclosure provide a semiconductor device of which the degree of integration and electrical characteristics are improved.

However, aspects of the inventive concept are not restricted to those set forth herein. The above and other aspects of the inventive concept will become more apparent to one of ordinary skill in the art to which the present disclosure pertains by referencing the detailed description of the present disclosure given below.

According to an aspect of the present disclosure, there is provided a semiconductor device comprising a first lower conductive line extending lengthwise in a first direction and including a first surface and a second surface opposing each other in a second direction, a first channel pattern disposed on the first surface of the first lower conductive line and connected to the first lower conductive line, a storage node pattern disposed on the first channel pattern and in contact with the first channel pattern, a second lower conductive line extending lengthwise in a third direction, overlapping the storage node pattern in the second direction, and disposed between the storage node pattern and the first channel pattern, a first upper conductive line disposed on the storage node pattern, extending in the third direction, and overlapping the second lower conductive line in the second direction, a second channel pattern disposed between the first upper conductive line and the storage node pattern and connected to the first upper conductive line, an upper gate insulating pattern disposed between the second channel pattern and the storage node pattern and a second upper conductive line extending lengthwise in the first direction, disposed on the second channel pattern, and connected to the second channel pattern, wherein a width of the storage node pattern in the first direction is greater than a width of the second lower conductive line in the first direction.

According to another aspect of the present disclosure, there is provided a semiconductor device comprising a first lower conductive line extending lengthwise in a first direction and including a first surface and a second surface opposing each other in a second direction, a lower protrusion insulating pattern disposed on the first surface of the first lower conductive line and including a lower channel trench extending in a third direction, a first channel pattern extending along the first surface of the first lower conductive line and a sidewall of the lower channel trench and connected to the first lower conductive line, a second lower conductive line disposed on the first channel pattern in the lower channel trench and extending in the third direction, an upper protrusion insulating pattern disposed on the lower protrusion insulating pattern and including an upper channel trench extending in the third direction, a second channel pattern including a horizontal portion extending in the first direction and a vertical portion disposed on a sidewall of the upper channel trench, and overlapping the first channel pattern in the second direction, a storage node pattern disposed between the first channel pattern and the second channel pattern in the upper channel trench and in contact with the first channel pattern, a first upper conductive line disposed on the second channel pattern and connected to the second channel pattern, an upper gate insulating pattern disposed between the second channel pattern and the storage node pattern and a second upper conductive line extending lengthwise in the first direction, disposed on the second channel pattern, and connected to the second channel pattern.

According to another aspect of the present disclosure, there is provided a semiconductor device comprising a first lower conductive line extending lengthwise in a first direction and including a first surface and a second surface opposing each other in a second direction,
a second lower conductive line disposed on the first surface of the first lower conductive line and extending lengthwise in a third direction, a first channel pattern disposed between the first lower conductive line and the second lower conductive line and connected to the first lower conductive line, a width of the first channel pattern in the first direction being greater than a width of the second lower conductive line in the first direction, a lower gate insulating pattern disposed between the first channel pattern and the second lower conductive line, a storage node pattern disposed on the first channel pattern and the lower gate insulating pattern and including a horizontal portion extending in the first direction and vertical portions extending in the second direction, the horizontal portion of the storage node pattern being in contact with the first channel pattern, and a width of the storage node pattern in the first direction being greater than the width of the second lower conductive line in the first direction, a first upper conductive line disposed between the vertical portions of the storage node pattern spaced apart from each other in the first direction, extending lengthwise in the third direction, and overlapping the second lower conductive line in the second direction, a second channel pattern disposed between the first upper conductive line and the storage node pattern and connected to the first upper conductive line, an upper gate insulating pattern disposed between the second channel pattern and the storage node pattern and a second upper conductive line extending lengthwise in the first direction, disposed on the second channel pattern, and connected to the second channel pattern.

It should be noted that the aspects of the inventive concept are not limited to those described above, and other aspects of the inventive concept will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a circuit diagram of a semiconductor device according to some example embodiments.

FIG. 2 is a schematic layout diagram of a semiconductor device according to some example embodiments.

FIG. 3 is a plan view of a cell array region of FIG. 2.

FIGS. 4 to 7 are cross-sectional views taken along lines A-A, B-B, C-C, and D-D of FIG. 3.

FIG. 8 is an enlarged view of portion P of FIG. 4.

FIG. 9 is a view illustrating a shape in which lower conductive lines and upper conductive lines of FIG. 4 are connected to contact plugs in a peripheral circuit region.

FIGS. 10 and 11 are views illustrating a semiconductor device according to some example embodiments.

FIGS. 12 and 13 are views illustrating a semiconductor device according to some example embodiments.

FIGS. 14 and 15 are views illustrating a semiconductor device according to some example embodiments.

FIGS. 16 and 17 are views illustrating a semiconductor device according to some example embodiments.

FIGS. 18 and 19 are views illustrating a semiconductor device according to some example embodiments.

FIGS. 20 and 21 are views illustrating a semiconductor device according to some example embodiments.

FIG. 22 is a view illustrating a semiconductor device according to some example embodiments.

FIGS. 23 and 24 are views illustrating semiconductor devices according to some example embodiments, respectively.

FIGS. 25 to 48 are intermediate step views illustrating a semiconductor device according to some example embodiments.

### DETAILED DESCRIPTION OF THE EMBODIMENTS

The present disclosure now will be described more fully hereinafter with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

It will be understood that, although the ordinal terms “first”, “second”, “third”, and so on may be used herein to describe various elements, components, regions, layers and/or sections, these elements, components, regions, layers, and/or sections should not be limited by these terms. These terms are used to distinguish one element, component, region, layer or section from another element, component, region, layer, or section. Thus, a first element, component, region, layer, or section described below could be termed a second element, component, region, layer, or section, without departing from the spirit and scope of the present disclosure. Additionally, although the drawings illustrate a first direction DR1, a second direction DR2, and a third direction DR3, the labels are for ease of description and the labels of the directions of the claims may not be the same as the labels used in the drawings. For example, the second direction of the claims may correspond to the third direction DR3 of the detailed description and the drawings, and the third direction of the claims may correspond to the second direction DR2 of the detailed description and the drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

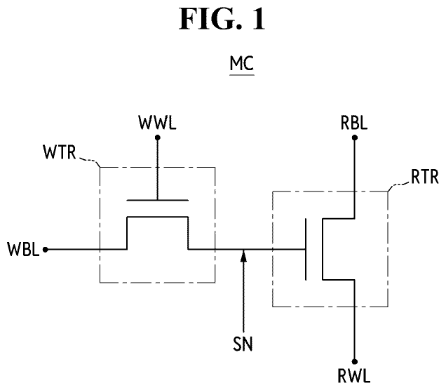

FIG. 1 is a circuit diagram of a semiconductor device according to some example embodiments.

Referring to FIG. 1, a memory cell MC may include a write transistor WTR and a read transistor RTR connected to the write transistor WTR. Although not illustrated, the semiconductor device according to some example embodiments may include a plurality of memory cells that are two-dimensionally or three-dimensionally arranged. The plurality of memory cells may be arranged as an array. In the following description, a single memory cell of the array may be described in detail with the understanding that the cell may be repeated in an array as part of a semiconductor device.

The write transistor WTR may include a write word line WWL connected to a gate terminal of the write transistor WTR and a write bit line WBL connected to a source terminal of the write transistor WTR. The read transistor RTR may include a read word line RWL and a read bit line RBL respectively connected to source/drain terminals of the read transistor RTR.

A drain terminal of the write transistor WTR may be connected to a gate terminal of the read transistor RTR. The drain terminal of the write transistor WTR may be named a storage node SN. The storage node SN may function as a gate of the read transistor RTR. The storage node SN may serve to store charges.

As an example, a program operation of the memory cell MC may be as follows. A voltage may be applied to the write word line WWL and the write bit line WBL, such that the write transistor WTR may be turned on. The write transistor WTR is turned on, such that an electrical signal (charge) may be transferred to (charged in) the storage node SN. Accordingly, the electrical signal of the write bit line WBL may be stored in the storage node SN, and consequently, a threshold voltage of the read transistor RTR may be changed.

As an example, a read operation of a memory cell MC may be as follows. The write transistor WTR may be turned off, the read word line RWL may be set to 0V, and a voltage may be applied to the read bit line RBL. The electrical signal stored in the storage node SN may be read through a current flowing through the read transistor RTR.

The semiconductor device including the memory cell MC may also be referred to as a 2T-0C (two transistor-zero capacitor) memory element. The semiconductor device according to some example embodiments may not include a separate capacitor for storing charges.

Accordingly, an area required for forming the capacitor may be reduced, such that it is possible to increase the degree of integration of the semiconductor device and reduce a cost required for manufacturing the semiconductor device. In addition, the capacitor is not formed, and thus, a memory cell array including a plurality of memory cells MC may be stacked in a vertical direction. Through this, the degree of integration of the semiconductor device may be increased.

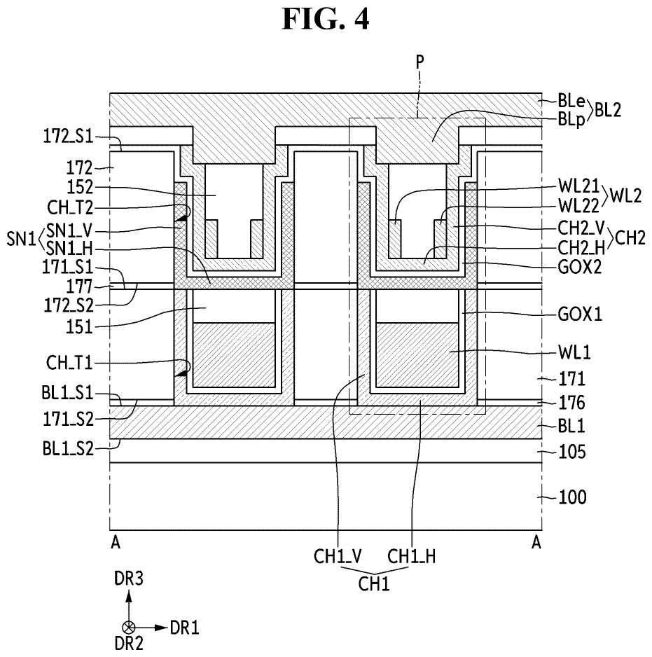

The semiconductor device including the 2T-0C memory element according to the present disclosure may include a vertical channel transistor (VCT). The vertical channel transistor may refer to a structure in which a channel of the transistor extends in a direction (third direction DR3 of FIG. 4) perpendicular to an upper surface of a substrate 100.

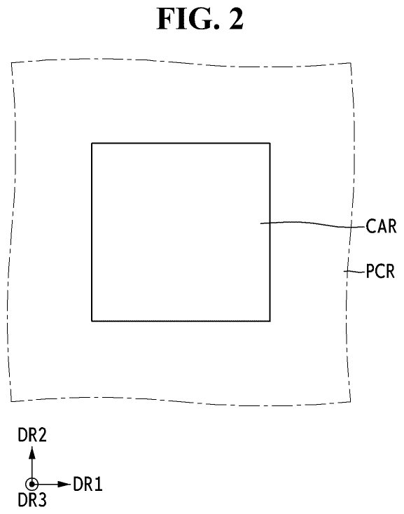

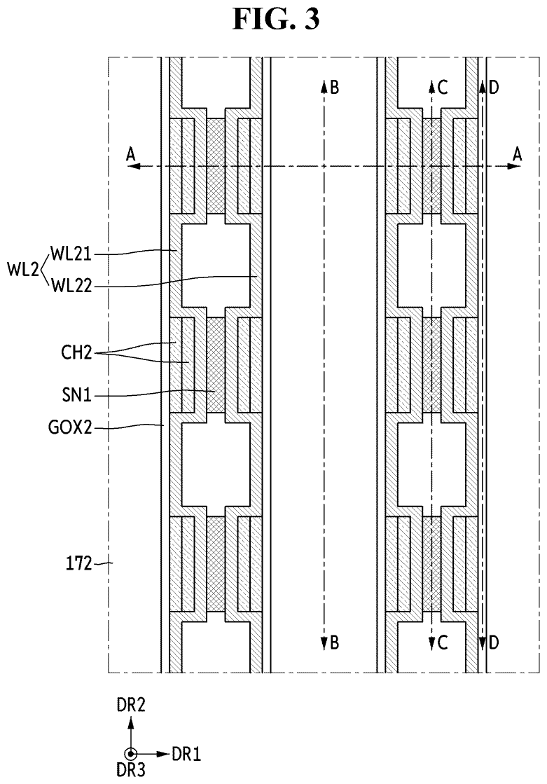

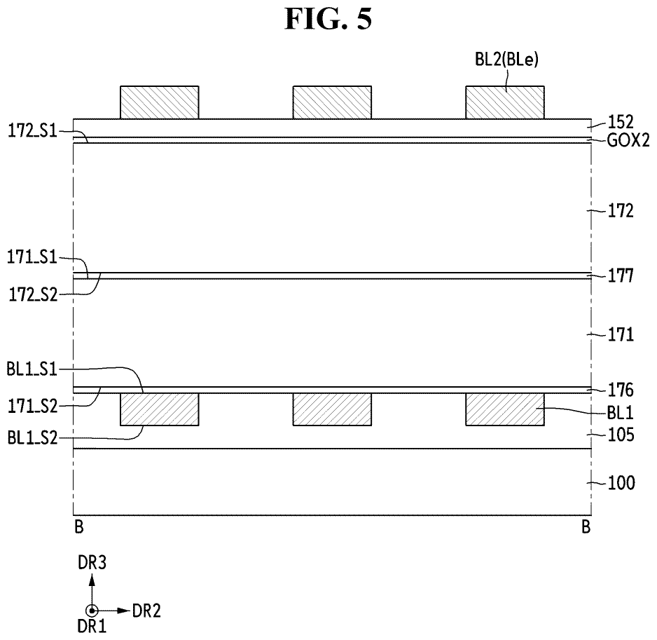

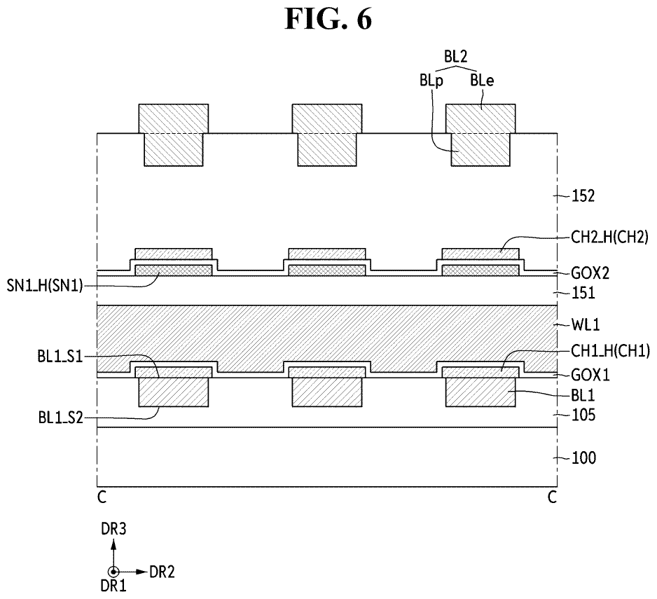

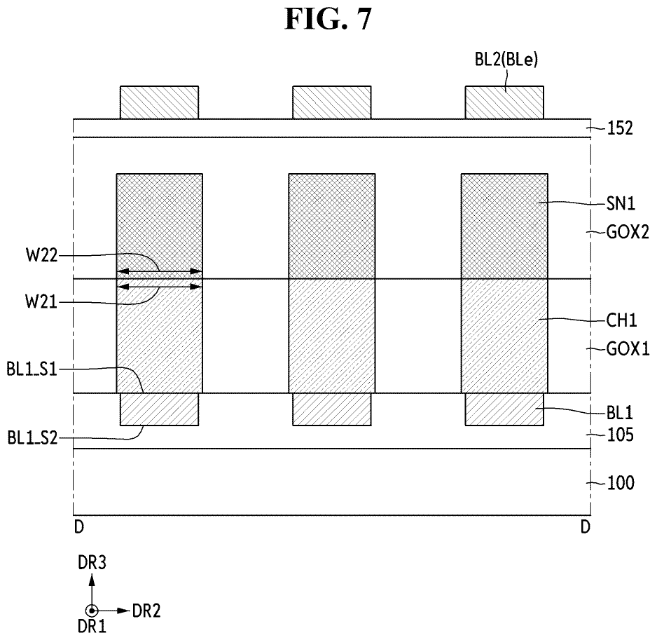

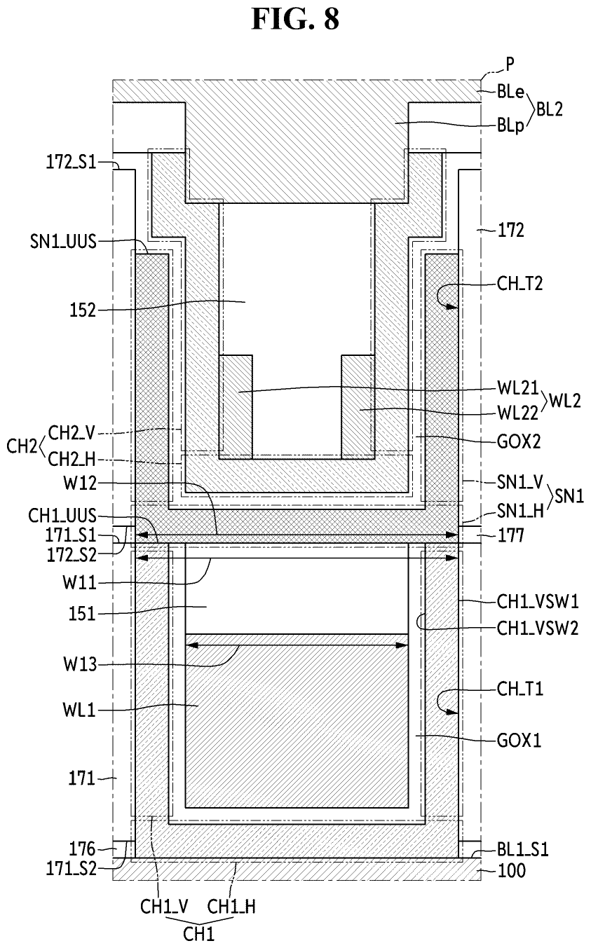

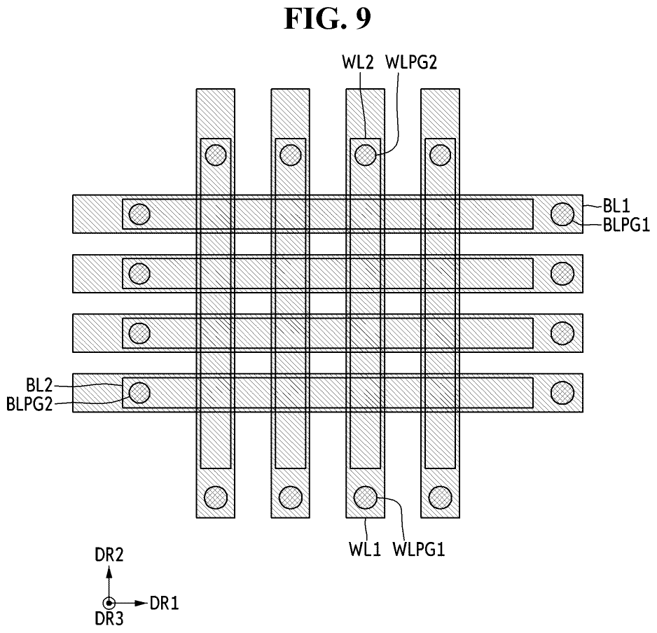

FIG. 2 is a schematic layout diagram of a semiconductor device according to some example embodiments. FIG. 3 is a plan view of a cell array region of FIG. 2. FIGS. 4 to 7 are cross-sectional views taken along lines A-A, B-B, C-C, and D-D. FIG. 8 is an enlarged view of portion P of FIG. 4. FIG. 9 is an illustrative view for describing a shape in which lower conductive lines and upper conductive lines of FIG. 4 are connected to contact plugs in a peripheral circuit region.

Referring to FIGS. 2 to 9, the semiconductor device according to some example embodiments may include a first lower conductive line BL1, a second lower conductive line WL1, a first upper conductive line WL2, a second upper conductive line BL2, a first channel pattern CH1, a second channel pattern CH2, and a first storage node pattern SN1.

A substrate 100 may include a cell array region CAR and a peripheral circuit region PCR. The memory cells MC (see FIG. 1) may be disposed on the substrate 100 of the cell array region CAR. The peripheral circuit region PCR may surround the cell array region CAR in a plan view (see FIG. 1).

As an example, the substrate 100 may be a silicon substrate or may include other materials such as silicon germanium, indium antimonide, a lead tellurium compound, indium arsenide, indium phosphide, gallium arsenide, or gallium antimonide. As another example, the substrate 100 may include a ceramic substrate, a quartz substrate, or a glass substrate. As still another example, the substrate 100 may include a flexible plastic substrate such as polyimide, polyethylene terephthalate (PET), polyethylene naphthalate (PEN), poly methyl methacrylate (PMMA), polycarbonate (PC), polyether sulfone (PES), or polyester.

A lower insulating film 105 may be disposed on the substrate 100. The lower insulating film 105 may be made of an insulating material.

The first lower conductive lines BL1 may be disposed on the substrate 100. The first lower conductive lines BL1 may be disposed on the lower insulating film 105.

Each first lower conductive line BL1 may extend lengthwise in a first direction DR1. The first lower conductive lines BL1 may be adjacent to each other in a second direction DR2.

The first lower conductive line BL1 may include a first surface BL1_S1 and a second surface BL1_S2 opposing each other in the third direction DR3. The second surface BL1_S2 of the first lower conductive line BL1 may face the substrate 100.

Here, the first direction DR1 and the second direction DR2 may be orthogonal to the third direction DR3. The first direction DR1 may cross the second direction DR2. For example, the third direction DR3 may be a thickness direction of the substrate 100. The first direction DR1 and the second direction DR2 may be parallel to the upper surface of the substrate 100.

For example, the first lower conductive line BL1 may correspond to the write bit line WBL of the write transistor WTR of FIG. 1.

The first lower conductive line BL1 may include a conductive material. The first lower conductive line BL1 may include, for example, at least one of a doped semiconductor material, conductive metal nitride, conductive metal silicon nitride, metal carbonitride, conductive metal silicide, conductive metal oxide, a two-dimensional (2D) material, and metal. It has been illustrated that the first lower conductive line BL1 is a single film, but the present disclosure is not limited thereto.

In the semiconductor device according to some example embodiments, the 2D material may be a metallic material and/or a semiconductor material. The 2D material may include a 2D allotrope or a 2D compound, for example, at least one of graphene, molybdenum disulfide (MoS₂), molybdenum diselenide (MoSe₂), tungsten diselenide (WSe₂), tungsten disulfide (WS₂), or combinations thereof, but is not limited thereto. That is, the above-described 2D materials have been enumerated only as an example, and thus, the 2D material that may be included in the semiconductor device according to the present disclosure is not limited by the above-described materials.

A first protrusion insulating pattern 171 may be disposed on the first lower conductive line BL1. The first protrusion insulating pattern 171 may be disposed on the first surface BL1_S1 of the first lower conductive line BL1. A first etch stop film 176 may be disposed between the first protrusion insulating pattern 171 and the first lower conductive line BL1.

The first protrusion insulating pattern 171 may include an insulating material. It has been illustrated that the first protrusion insulating pattern 171 is a single film, but this is only for convenience of explanation, and the present disclosure is not limited thereto. The first etch stop film 176 may be formed of an insulating material. The first etch stop film 176 may include a material having an etching selectivity with respect to the first protrusion insulating pattern 171. Unlike the example illustrated, in some examples, the first etch stop film 176 may not be disposed between the first protrusion insulating pattern 171 and the first lower conductive line BL1.

The first protrusion insulating pattern 171 may include a first surface 171_S1 and a second surface 171_S2 opposing each other in the third direction DR3. The second surface 171_S2 of the first protrusion insulating pattern 171 may face the first lower conductive line BL1. For example, the first surface 171_S1 of the first protrusion insulating pattern 171 may be an upper surface of the first protrusion insulating pattern 171. The second surface 171_S2 of the first protrusion insulating pattern 171 may be a bottom surface of the first protrusion insulating pattern 171.

The first protrusion insulating pattern 171 may include a plurality of first channel trenches CH_T1. Each first channel trench CH_T1 may extend to be elongated in the second direction DR2. Adjacent first channel trenches CH_T1 may be spaced apart from each other in the first direction DR1.

Each first channel trench CH_T1 may cross the first lower conductive line BL1. One first channel trench CH_T1 may expose a plurality of first lower conductive lines BL1 adjacent to each other in the second direction DR2. The first channel trench CH_T1 may expose the first surface BL1_S1 of the first lower conductive line BL1.

A bottom surface of each first channel trench CH_T1 may be defined by the first lower conductive line BL1 and the lower insulating film 105. A sidewall of each first channel trench CH_T1 may be defined by the first protrusion insulating pattern 171 and the first etch stop film 176.

The first channel patterns CH1 may be disposed on the respective first lower conductive lines BL1. For example, the first channel patterns CH1 may be disposed on the first surfaces BL1_S1 of the respective first lower conductive lines BL1. A plurality of first channel patterns CH1 may be connected to one first lower conductive line BL1. The plurality of first channel patterns CH1 disposed on one first lower conductive line BL1 are spaced apart from each other in the first direction DR1.

The first channel pattern CH1 may be disposed in the first channel trench CH_T1 extending in the second direction DR2. The plurality of first channel patterns CH1 may be disposed in one first channel trench CH_T1. The plurality of first channel patterns CH1 disposed in the first channel trench CH_T1 are spaced apart from each other in the second direction DR2. For example, the first channel patterns CH1 may be two-dimensionally arranged along the first direction DR1 and the second direction DR2 crossing each other.

The first channel pattern CH1 may extend along the sidewall and the bottom surface of the first channel trench CH_T1. For example, the first channel pattern CH1 may be in contact with the first protrusion insulating pattern 171. In the semiconductor device according to some example embodiments, the first channel pattern CH1 may have a “U” shape in a cross section taken along the first direction DR1.

The first channel pattern CH1 may include a horizontal portion CH1_H and a plurality of vertical portions CH1_V. The vertical portions CH1_V of the first channel pattern CH1 are spaced apart from each other in the first direction DR1. The horizontal portion CH1_H of the first channel pattern CH1 is directly connected to the vertical portions CH1_V of the first channel pattern CH1.

The horizontal portion CH1_H of the first channel pattern CH1 may extend along the bottom surface of the first channel trench CH_T1. In cross section as illustrated in FIG. 4, the horizontal portion CH1_H of the first channel pattern CH1 may extend in the first direction DR1. The horizontal portion CH1_H of the first channel pattern CH1 may be connected to the first surface BL1_S1 of the first lower conductive line BL1.

The vertical portion CH1_V of the first channel pattern CH1 is disposed on the sidewall of the first channel trench CH_T1. The vertical portion CH1_V of the first channel pattern CH1 may extend along the sidewall of the first channel trench CH_T1. The vertical portion CH1_V of the first channel pattern CH1 may extend to the first surface 171_S1 of the first protrusion insulating pattern 171.

The vertical portion CH1_V of the first channel pattern CH1 may protrude from the horizontal portion CH1_H of the first channel pattern CH1 in the third direction DR3. The vertical portion CH1_V of the first channel pattern CH1 may extend in the third direction DR3. The vertical portion CH1_V of the first channel pattern CH1 may include an uppermost surface CH1_UUS of the first channel pattern CH1. For example, the uppermost surface CH1_UUS of the first channel pattern CH1 may be a surface of the first channel pattern CH1 farthest from the first lower conductive line BL1.

The vertical portion CH1_V of the first channel pattern CH1 may include a first sidewall CH1_VSW1 and a second sidewall CH1_VSW2 opposing each other in the first direction DR1. The first sidewall CH1_VSW1 of the vertical portion CH1_V of the first channel pattern CH1 may face the first protrusion insulating pattern 171. The second sidewall CH1_VSW2 of the vertical portion CH1_V of the first channel pattern CH1 may face the second lower conductive line WL1.

As an example, the first channel pattern CH1 may include an oxide semiconductor material. The first channel pattern CH1 may include, for example, metal oxide semiconductor material. As an example, the first channel pattern CH1 may be an amorphous metal oxide film. As another example, the first channel pattern CH1 may be a polycrystalline metal oxide film. As still another example, the first channel pattern CH1 may be in a state in which an amorphous metal oxide film and a polycrystalline metal oxide film are combined with each other. As still another example, the first channel pattern CH1 may be a c-axis aligned crystalline (CAAC) metal oxide film.

The first channel pattern CH1 may include, for example, one of indium oxide, tin oxide, zinc oxide, In—Zn-based oxide (IZO), Sn—Zn-based oxide, Al—Zn-based oxide, Zn—Mg-based oxide, Sn—Mg-based oxide, In—Mg-based oxide, In—Ga-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, and In—Hf—Al—Zn-based oxide, but is not limited thereto.

Here, the In—Ga—Zn-based oxide refers to oxide having In, Ga, and Zn as main components rather than a ratio between In, Ga, and Zn. That is, taking indium gallium zinc oxide (IGZO) as an example, the first channel pattern CH1 may include indium gallium zinc oxide (IGZO:InₓGa_{y}Zn_{z}O). IGZO (In:Ga:Zn=1:1:1) in which indium, gallium, and zinc are included in the same ratio may be In—Ga—Zn-based oxide. Ga-rich IGZO may have a higher gallium ratio than IGZO (In:Ga:Zn=1:1:1) and have a lower indium ratio than IGZO (In:Ga:Zn=1:1:1). The Ga-rich IGZO may also be In—Ga—Zn-based oxide. In addition, In-rich IGZO may have a higher indium ratio than IGZO (In:Ga:Zn=1:1:1) and have a lower gallium ratio than IGZO (In:Ga:Zn=1:1:1). The In-rich IGZO may also be In—Ga—Zn-based oxide.

The above description has been provided using IGZO, but the present disclosure is not limited thereto. When the first channel pattern CH1 includes ternary or higher metal oxide, the above description may be applied. In addition, when the first channel pattern CH1 includes In—Ga—Zn-based oxide, the first channel pattern CH1 may further include a doped metal element other than In, Ga, and Zn.

The second lower conductive line WL1 may be disposed on the first channel pattern CH1. The second lower conductive line WL1 may be disposed in the first channel trench CH_T1. The second lower conductive line WL1 may extend lengthwise in the second direction DR2.

The second lower conductive line WL1 may be disposed on the horizontal portion CH1_H of the first channel pattern CH1. The second lower conductive line WL1 may be disposed between the vertical portions CH1_V of the first channel patterns CH1 adjacent to each other in the first direction DR1.

The second lower conductive line WL1 may be disposed between the first channel pattern CH1 and the first storage node pattern SN1. The second lower conductive line WL1 may overlap the first storage node pattern SN1 in the third direction DR3.

The second lower conductive line WL1 may be disposed on the second sidewall CH1_VSW2 of the vertical portion CH1_V of the first channel pattern CH1. The second lower conductive line WL1 is not disposed on the first sidewall CH1_VSW1 of the vertical portion CH1_V of the first channel pattern CH1.

For example, the second lower conductive line WL1 may correspond to the write word line WWL of the write transistor WTR of FIG. 1.

A width W13 of the second lower conductive line WL1 in the first direction DR1 is smaller than a width W11 of the first channel pattern CH1 in the first direction DR1.

The second lower conductive line WL1 may include a conductive material. The second lower conductive line WL1 may include, for example, at least one of a doped semiconductor material, conductive metal nitride, conductive metal silicon nitride, metal carbonitride, conductive metal silicide, conductive metal oxide, a 2D material, and metal. It has been illustrated that the second lower conductive line WL1 is a single film, but the present disclosure is not limited thereto.

A first lower gate insulating pattern GOX1 may be disposed between the first channel pattern CH1 and the second lower conductive line WL1. The first lower gate insulating pattern GOX1 may be disposed between the first channel pattern CH1 and the first storage node pattern SN1.

The first lower gate insulating pattern GOX1 may extend along an inner profile of the first channel pattern CH1. The first lower gate insulating pattern GOX1 may extend along the second sidewall CH1_VSW2 of the vertical portion CH1_V of the first channel pattern CH1. The first lower gate insulating pattern GOX1 is not disposed on the first sidewall CH1_VSW1 of the vertical portion CH1_V of the first channel pattern CH1.

The first lower gate insulating pattern GOX1 may include silicon oxide, silicon oxynitride, a high-k insulating material having a dielectric constant higher than that of silicon oxide, or combinations thereof. The high-k insulating material may include metal oxide or metal oxynitride. For example, the high-k insulating material may include at least one of hafnium oxide, hafnium silicon oxide, hafnium silicon oxynitride, hafnium tantalum oxide, hafnium titanium oxide, hafnium zirconium oxide, zirconium oxide, or aluminum oxide, but is not limited thereto.

A first lower isolation insulating pattern 151 may be disposed on the first lower gate insulating pattern GOX1. The first lower isolation insulating pattern 151 may fill the first channel trench CH_T1 remaining after the first channel pattern CH1, the first lower gate insulating pattern GOX1, and the second lower conductive line WL1 are formed.

The first lower isolation insulating pattern 151 may be disposed on the second lower conductive line WL1 extending lengthwise in the second direction DR2. The first lower isolation insulating pattern 151 may extend along an upper surface of the second lower conductive line WL1. The first lower isolation insulating pattern 151 includes an insulating material.

The first lower gate insulating pattern GOX1 may extend to the uppermost surface CH1_UUS of the first channel pattern CH1, but is not limited thereto. In such a case, an uppermost surface of the first lower gate insulating pattern GOX1 may be covered by the first lower isolation insulating pattern 151.

A second protrusion insulating pattern 172 may be disposed on the first protrusion insulating pattern 171. The second protrusion insulating pattern 172 may be disposed on the first channel pattern CH1 and the first lower isolation insulating pattern 151. A second etch stop film 177 may be disposed between the first protrusion insulating pattern 171 and the second protrusion insulating pattern 172.

The second protrusion insulating pattern 172 may include an insulating material. It has been illustrated that the second protrusion insulating pattern 172 is a single film, but this is only for convenience of explanation, and the present disclosure is not limited thereto. The second etch stop film 177 may be formed of an insulating material. The second etch stop film 177 may include a material having an etching selectivity with respect to the second protrusion insulating pattern 172.

Unlike the example illustrated, in some examples, the second etch stop film 177 may not be disposed between the first protrusion insulating pattern 171 and the second protrusion insulating pattern 172. When the first protrusion insulating pattern 171 and the second protrusion insulating pattern 172 include the same material and the second etch stop film 177 is not disposed, a boundary surface between the first protrusion insulating pattern 171 and the second protrusion insulating pattern 172 may not be apparent. In such a case, a boundary between the first protrusion insulating pattern 171 and the second protrusion insulating pattern 172 may become apparent from the uppermost surface CH1_UUS of the first channel pattern CH1.

The second protrusion insulating pattern 172 may include a first surface 172_S1 and a second surface 172_S2 opposing each other in the third direction DR3. The second surface 172_S2 of the second protrusion insulating pattern 172 may face the first lower conductive line BL1. For example, the first surface 172_S1 of the second protrusion insulating pattern 172 may be an upper surface of the second protrusion insulating pattern 172. The second surface 172_S2 of the second protrusion insulating pattern 172 may be a bottom surface of the second protrusion insulating pattern 172.

The second protrusion insulating pattern 172 may include a plurality of second channel trenches CH_T2. Each second channel trench CH_T2 may extend to be elongated in the second direction DR2. Adjacent second channel trenches CH_T2 may be spaced apart from each other in the first direction DR1. Each second channel trench CH_T2 may overlap each corresponding first channel trench CH_T1 in the third direction DR3.

The second channel trench CH_T2 may expose the first lower isolation insulating pattern 151. One second channel trench CH_T2 may expose a plurality of first channel patterns CH1 aligned with each other in the second direction DR2. The second channel trench CH_T2 may expose the uppermost surface CH1_UUS of the first channel pattern CH1.

At least a portion of a bottom surface of each second channel trench CH_T2 may be defined by the first lower isolation insulating pattern 151 and the first channel patterns CH1. A sidewall of each second channel trench CH_T2 may be defined by the second protrusion insulating pattern 172 and the second etch stop film 177.

The first storage node patterns SN1 may be disposed on the first protrusion insulating pattern 171. The first storage node patterns SN1 may be disposed on the first lower gate insulating pattern GOX1. Each first storage node pattern SN1 may be disposed on the corresponding first channel pattern CH1. Each first storage node pattern SN1 may be disposed between the corresponding first channel pattern CH1 and second channel pattern CH2.

The first storage node pattern SN1 may be connected to the first channel pattern CH1. The first storage node pattern SN1 may be connected to the uppermost surface CH1_UUS of the first channel pattern CH1. The first storage node pattern SN1 is electrically connected to the first channel pattern CH1.

For example, the first storage node pattern SN1 may be in contact with the first channel pattern CH1. When the first lower gate insulating pattern GOX1 extends to the uppermost surface CH1_UUS of the first channel pattern CH1, the first storage node pattern SN1 may be in contact with the first lower gate insulating pattern GOX1.

The first storage node patterns SN1 may be disposed in the second channel trench CH_T2 extending in the second direction DR2. A plurality of first storage node patterns SN1 may be disposed in one second channel trench CH_T2. The plurality of first storage node patterns SN1 disposed in the second channel trench CH_T2 are spaced apart from each other in the second direction DR2. For example, the first storage node patterns SN1 may be two-dimensionally arranged along the first direction DR1 and the second direction DR2 crossing each other.

The first storage node pattern SN1 may extend along the sidewall and the bottom surface of the second channel trench CH_T2. For example, the first storage node pattern SN1 may be in contact with the second protrusion insulating pattern 172. In the semiconductor device according to some example embodiments, the first storage node pattern SN1 may have a “U” shape in a cross section taken along the first direction DR1.

The first storage node pattern SN1 may include a horizontal portion SN1_H and a plurality of vertical portions SN1_V. The vertical portions SN1_V of the first storage node pattern SN1 are spaced apart from each other in the first direction DR1. The horizontal portion SN1_H of the first storage node pattern SN1 is directly connected to the vertical portions SN1_V of the first storage node pattern SN1.

The horizontal portion SN1_H of the first storage node pattern SN1 may extend along the bottom surface of the second channel trench CH_T2. In cross section as illustrated in FIG. 4, the horizontal portion SN1_H of the first storage node pattern SN1 may extend in the first direction DR1. The horizontal portion SN1_H of the first storage node pattern SN1 may be connected to the first channel pattern CH1. The horizontal portion SN1_H of the first storage node pattern SN1 may be in contact with the first channel pattern CH1.

The vertical portion SN1_V of the first storage node pattern SN1 is disposed on the sidewall of the second channel trench CH_T2. The vertical portion SN1_V of the first storage node pattern SN1 may extend along a portion of the sidewall of the second channel trench CH_T2. The vertical portion SN1_V of the first storage node pattern SN1 does not extend to the first surface 172_S1 of the second protrusion insulating pattern 172.

The vertical portion SN1_V of the first storage node pattern SN1 may protrude from the horizontal portion SN1_H of the first storage node pattern SN1 in the third direction DR3. The vertical portion SN1_V of the first storage node pattern SN1 may extend in the third direction DR3. The vertical portion SN1_V of the first storage node pattern SN1 may include an uppermost surface SN1_UUS of the first storage node pattern SN1. Based on the first surface BL1_S1 of the first lower conductive line BL1, the uppermost surface SN1_UUS of the first storage node pattern SN1 is lower than the first surface 172_S1 of the second protrusion insulating pattern 172.

A width W12 of the first storage node pattern SN1 in the first direction DR1 is greater than the width W13 of the second lower conductive line WL1 in the first direction DR1.

In the semiconductor device according to some example embodiments, the width W11 of the first channel pattern CH1 in the first direction DR1 may be the same as the width W12 of the first storage node pattern SN1 in the first direction DR1. A width W21 of the first channel pattern CH1 in the second direction DR2 may be the same as a width W22 of the first storage node pattern SN1 in the second direction DR2.

For example, the widths W11 and W21 of the first channel pattern CH1 and the widths W12 and W22 of the first storage node pattern SN1 may be widths measured on the first surface 171_S1 of the first protrusion insulating pattern 171. Alternatively, the widths W11 and W21 of the first channel pattern CH1 and the widths W12 and W22 of the first storage node pattern SN1 may be measured at a portion where the first channel pattern CH1 and the first storage node pattern SN1 are connected to each other.

The first storage node pattern SN1 may be a portion corresponding to the storage node SN of FIG. 1.

The first storage node pattern SN1 may include a conductive material. The first storage node pattern SN1 may include, for example, at least one of a doped semiconductor material, conductive metal nitride, conductive metal silicon nitride, metal carbonitride, conductive metal silicide, conductive metal oxide, a 2D material, and metal. It has been illustrated that the first storage node pattern SN1 is a single film, but the present disclosure is not limited thereto.

For example, a width of the first channel trench CH_T1 in the first direction DR1 may be the width W11 of the first channel pattern CH1 in the first direction DR1. A width of the second channel trench CH_T2 in the first direction DR1 may be the width W12 of the first storage node pattern SN1 in the first direction DR1. For example, the width W11 of the first channel trench CH_T1 in the first direction DR1 may be the same as the width W12 of the second channel trench CH_T2 in the first direction DR1.

The first channel trench CH_T1 may include one sidewall and the other sidewall. The second channel trench CH_T2 may include one sidewall and the other sidewall. A position of one sidewall of the first channel trench CH_T1 may be a position corresponding to one sidewall of the second channel trench CH_T2. A position of the other sidewall of the first channel trench CH_T1 may be a position corresponding to the other sidewall of the second channel trench CH_T2. In the semiconductor device according to some example embodiments, one sidewall of the first channel trench CH_T1 may be aligned with one sidewall of the second channel trench CH_T2 in the third direction DR3. The other sidewall of the first channel trench CH_T1 may be aligned with the other sidewall of the second channel trench CH_T2 in the third direction DR3.

The second channel pattern CH2 may be disposed on the first storage node pattern SN1. For example, each second channel pattern CH2 may be disposed on the corresponding first storage node pattern SN1. Each second channel pattern CH2 may overlap the corresponding first channel pattern CH1 in the third direction DR3. The second channel pattern CH2 may be disposed between the first upper conductive line WL2 and the first storage node pattern SN1.

The second channel pattern CH2 may be disposed in the second channel trench CH_T2 extending in the second direction DR2. A plurality of second channel patterns CH2 may be disposed in one second channel trench CH_T2. The plurality of second channel patterns CH2 disposed in the second channel trench CH_T2 are spaced apart from each other in the second direction DR2. For example, the second channel patterns CH2 may be two-dimensionally arranged along the first direction DR1 and the second direction DR2 crossing each other.

The second channel pattern CH2 may extend along the sidewall and the bottom surface of the second channel trench CH_T2. In the semiconductor device according to some example embodiments, the second channel pattern CH2 may have a shape similar to a “U” shape in a cross section taken along the first direction DR1.

The second channel pattern CH2 may include a horizontal portion CH2_H and a plurality of vertical portions CH2_V. The horizontal portion CH2_H of the second channel pattern CH2 may extend along the bottom surface of the second channel trench CH_T2. In cross section as illustrated in FIG. 4, the horizontal portion CH2_H of the second channel pattern CH2 may extend in the first direction DR1.

The vertical portion CH2_V of the second channel pattern CH2 is disposed on the sidewall of the second channel trench CH_T2. The vertical portion CH2_V of the second channel pattern CH2 may protrude from the horizontal portion CH2_H of the second channel pattern CH2 in the third direction DR3. The vertical portion CH2_V of the second channel pattern CH2 may extend in the third direction DR3.

As an example, the second channel pattern CH2 may include an oxide semiconductor material. The second channel pattern CH2 may include, for example, metal oxide semiconductor material. The metal oxide included in the second channel pattern CH2 may be substantially the same as or the same as the metal oxide included in the first channel pattern CH1 and a description thereof is therefore omitted.

A first upper gate insulating pattern GOX2 may be disposed between the second channel pattern CH2 and the first storage node pattern SN1. The first upper gate insulating pattern GOX2 may cover the uppermost surface SN1_UUS of the first storage node pattern SN1.

The first upper gate insulating pattern GOX2 may extend along an inner profile of the first storage node pattern SN1. The first upper gate insulating pattern GOX2 may extend along a portion of the sidewall of the second channel trench CH_T2. The first upper gate insulating pattern GOX2 may extend along the first surface 172_S1 of the second protrusion insulating pattern 172.

The first upper gate insulating pattern GOX2 may include silicon oxide, silicon oxynitride, a high-k insulating material having a dielectric constant higher than that of silicon oxide, or combinations thereof.

The first upper conductive line WL2 may be disposed on the first storage node pattern SN1. For example, the first upper conductive line WL2 may be disposed on the second channel pattern CH2. The first upper conductive line WL2 may extend lengthwise in the second direction DR2.

The first upper conductive line WL2 may be connected to the second channel pattern CH2. For example, the first upper conductive line WL2 may be electrically connected to the second channel pattern CH2. One first upper conductive line WL2 may be connected to a plurality of second channel patterns CH2 arranged in the second direction DR2.

The first upper conductive line WL2 may be disposed in the second channel trench CH_T2. The first upper conductive line WL2 may be disposed between the vertical portions CH2_V of the second channel pattern CH2 spaced apart from each other in the first direction DR1. The first upper conductive line WL2 may be disposed between the vertical portions SN1_V of the first storage node pattern SN1 spaced apart from each other in the first direction DR1. For example, the first upper conductive line WL2 may overlap the second lower conductive line WL1 in the third direction DR3.

The first upper conductive line WL2 may include a first upper sub-conductive line WL21 and a second upper sub-conductive line WL22. Each of the first upper sub-conductive line WL21 and the second upper sub-conductive line WL22 may extend lengthwise in the second direction DR2. The first upper sub-conductive line WL21 and the second upper sub-conductive line WL22 may be spaced apart from each other in the first direction DR1. The first upper sub-conductive line WL21 and the second upper sub-conductive line WL22 may be electrically connected to each other.

The first upper conductive line WL2 may include a conductive material. The first upper conductive line WL2 may include, for example, at least one of a doped semiconductor material, conductive metal nitride, conductive metal silicon nitride, metal carbonitride, conductive metal silicide, conductive metal oxide, a 2D material, and metal. The first upper sub-conductive line WL21 and the second upper sub-conductive line WL22 may include the same material. It has been illustrated that each of the first upper sub-conductive line WL21 and the second upper sub-conductive line WL22 is a single film, but the present disclosure is not limited thereto.

A first upper isolation insulating pattern 152 may be disposed on the second channel pattern CH2. The first upper isolation insulating pattern 152 may be disposed in the second channel trench CH_T2. A portion of the first upper isolation insulating pattern 152 may be disposed on the first surface 172_S1 of the second protrusion insulating pattern 172. Unlike illustrated, the first upper isolation insulating pattern 152 may not be disposed on the first surface 172_S1 of the second protrusion insulating pattern 172.

The first upper isolation insulating pattern 152 may be disposed on the first upper conductive line WL2. In the semiconductor device according to some example embodiments, the first upper isolation insulating pattern 152 may be disposed between the first upper sub-conductive line WL21 and the second upper sub-conductive line WL22 spaced apart from each other in the first direction DR1. The first upper isolation insulating pattern 152 includes an insulating material.

The second upper conductive line BL2 may be disposed on the second channel pattern CH2. The second upper conductive line BL2 may extend lengthwise in the first direction DR1. The second upper conductive lines BL2 may be adjacent to each other in the second direction DR2.

The second upper conductive line BL2 may be connected to the second channel pattern CH2. For example, the second upper conductive line BL2 is electrically connected to the second channel pattern CH2. The second upper conductive line BL2 may be connected to the vertical portion CH2_V of the second channel pattern CH2. One second upper conductive line BL2 may be connected to a plurality of second channel patterns CH2 arranged in the first direction DR1.

The second upper conductive line BL2 may include an extension portion BLe and a plurality of protrusion portions BLp. The extension portion BLe of the second upper conductive line BL2 may extend lengthwise in the second direction DR2. Between the extension portion BLe of the second upper conductive line BL2 and the second protrusion insulating pattern 172, a portion of the first upper isolation insulating pattern 152 may be disposed.

The protrusion portion BLp of the second upper conductive line BL2 may protrude in the third direction DR3. The protrusion portion BLp of the second upper conductive line BL2 may protrude from the extension portion BLe of the second upper conductive line BL2 toward the second channel pattern CH2. The protrusion portion BLp of each second upper conductive line BL2 may be disposed between the vertical portions CH2_V of the second channel pattern CH2 spaced apart from each other in the first direction DR1.

As an example, the first upper conductive line WL2 may correspond to the read word line RWL of the read transistor RTR of FIG. 1. The second upper conductive line BL2 may correspond to the read bit line RBL of the read transistor RTR.

As another example, the first upper conductive line WL2 may correspond to the read bit line RBL of the read transistor RTR of FIG. 1. The second upper conductive line BL2 may correspond to the read word line RWL of the read transistor RTR.

The second upper conductive line BL2 may include a conductive material. The second upper conductive line BL2 may include, for example, a doped semiconductor material, conductive metal nitride, conductive metal silicon nitride, metal carbonitride, conductive metal silicide, conductive metal oxide, a 2D material, or a metal. It has been illustrated that the second upper conductive line BL2 is a single film, but the present disclosure is not limited thereto.

In FIGS. 2 and 9, the first lower conductive line BL1, the second lower conductive line WL1, the first upper conductive line WL2, and the second upper conductive line BL2 may extend to the peripheral circuit region PCR.

For example, in a plan view, a length of the first lower conductive line BL1 in the first direction DR1 may be greater than a length of the second upper conductive line BL2 in the first direction DR1. In other words, the first lower conductive line BL1 may protrude more than the second upper conductive line BL2 in the first direction DR1. The first lower conductive line BL1 may include a first portion that overlaps the second upper conductive line BL2 in the third direction DR3 and a second portion that does not overlap the second upper conductive line BL2 in the third direction DR3.

A first lower contact plug BLPG1 may be electrically connected to the first lower conductive line BL1. For example, the first lower contact plug BLPG1 may be connected to the second portion of the first lower conductive line BL1. A second upper contact plug BLPG2 may be electrically connected to the second upper conductive line BL2. A shape in which the first lower contact plug BLPG1 and the second upper contact plug BLPG2 are arranged in a plan view is only for convenience of explanation, and embodiments of the inventive concept are not limited thereto.

Unlike the example illustrated, in a plan view, in some examples a length of the first lower conductive line BL1 in the first direction DR1 may be smaller than a length of the second upper conductive line BL2 in the first direction DR1. In such a case, the second upper conductive line BL2 may include a first portion that overlaps the first lower conductive line BL1 in the third direction DR3 and a second portion that does not overlap the first lower conductive line BL1 in the third direction DR3.

For example, in a plan view, a length of the second lower conductive line WL1 in the second direction DR2 may be greater than a length of the first upper conductive line WL2 in the second direction DR2. In other words, the second lower conductive line WL1 may protrude more than the first upper conductive line WL2 in the second direction DR2. The second lower conductive line WL1 may include a first portion that overlaps the first upper conductive line WL2 in the third direction DR3 and a second portion that does not overlap the first upper conductive line WL2 in the third direction DR3.

A second lower contact plug WLPG1 may be electrically connected to the second lower conductive line WL1. For example, the second lower contact plug WLPG1 may be connected to the second portion of the second lower conductive line WL1. A first upper contact plug WLPG2 may be electrically connected to the first upper conductive line WL2. A shape in which the second lower contact plug WLPG1 and the first upper contact plug WLPG2 are arranged in a plan view is only for convenience of explanation, and the technical spirit of the present disclosure is not limited thereto.

The first upper conductive line WL2 may include the first upper sub-conductive line WL21 and the second upper sub-conductive line WL22 spaced apart from each other in the first direction DR1, but the first upper sub-conductive line WL21 and the second upper sub-conductive line WL22 may be electrically connected to one first upper contact plug WLPG2.

Unlike the example illustrated, in a plan view, in some examples a length of the second lower conductive line WL1 in the second direction DR2 may be smaller than a length of the first upper conductive line WL2 in the second direction DR2. In such a case, the first upper conductive line WL2 may include a first portion that overlaps the second lower conductive line WL1 in the third direction DR3 and a second portion that does not overlap the second lower conductive line WL1 in the third direction DR3.

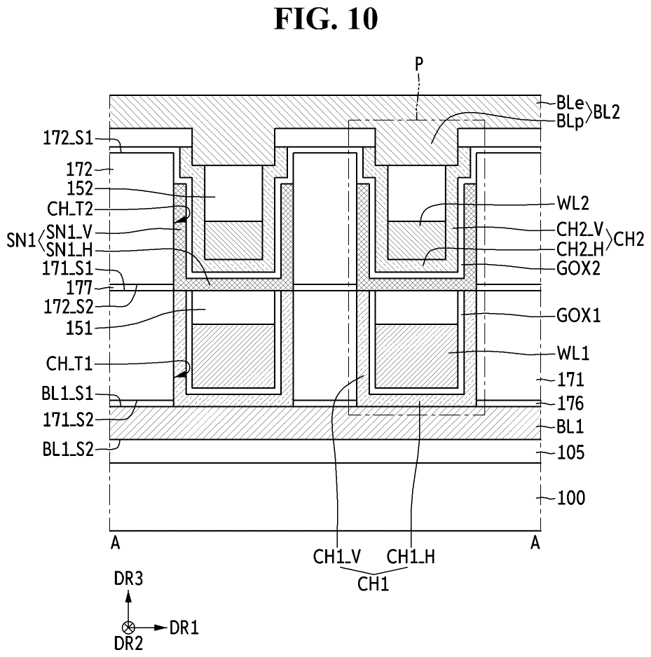

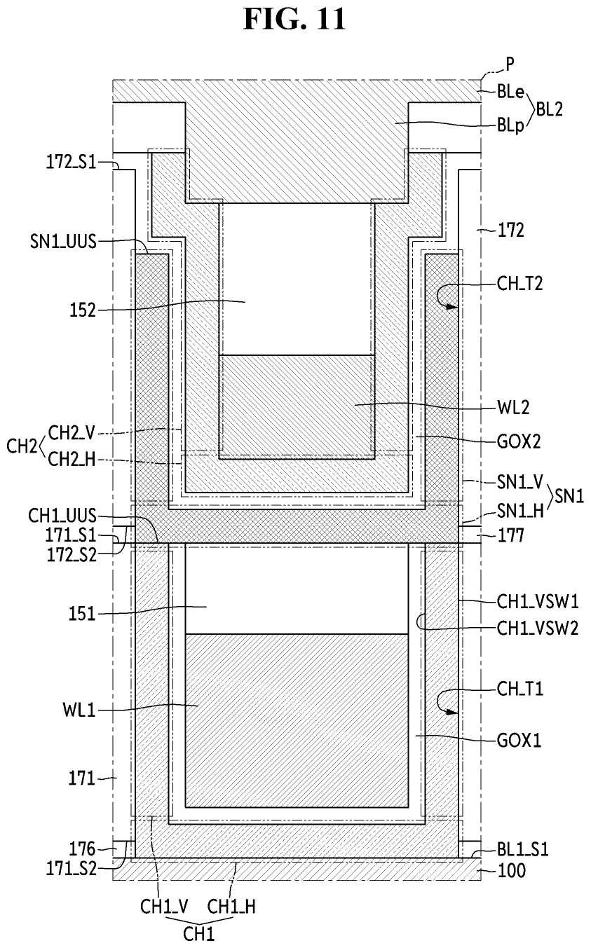

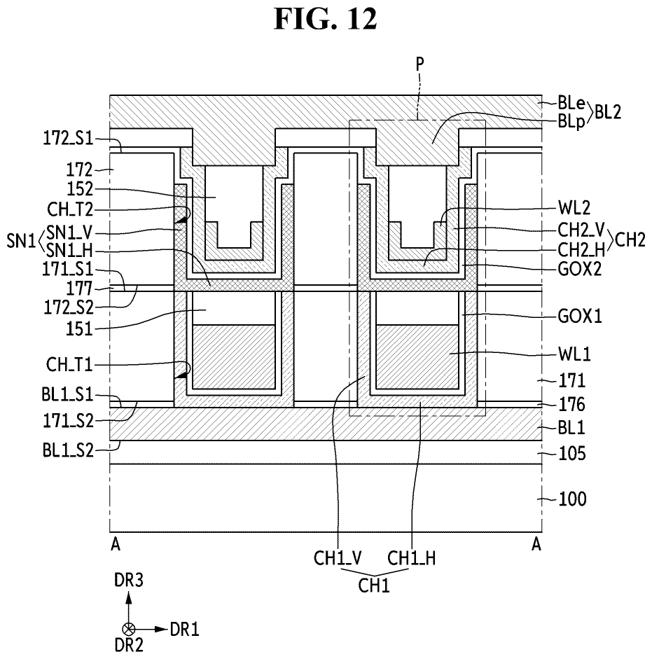

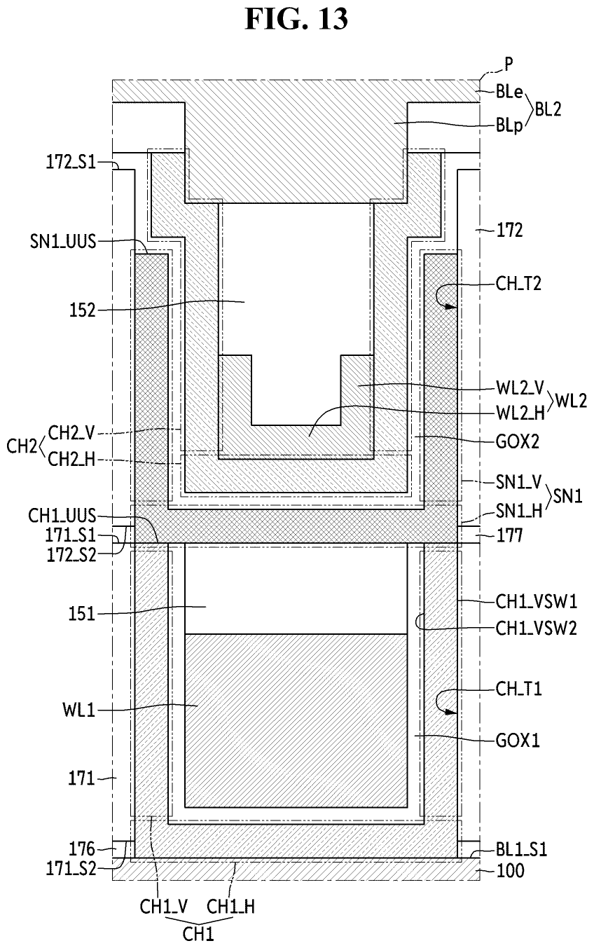

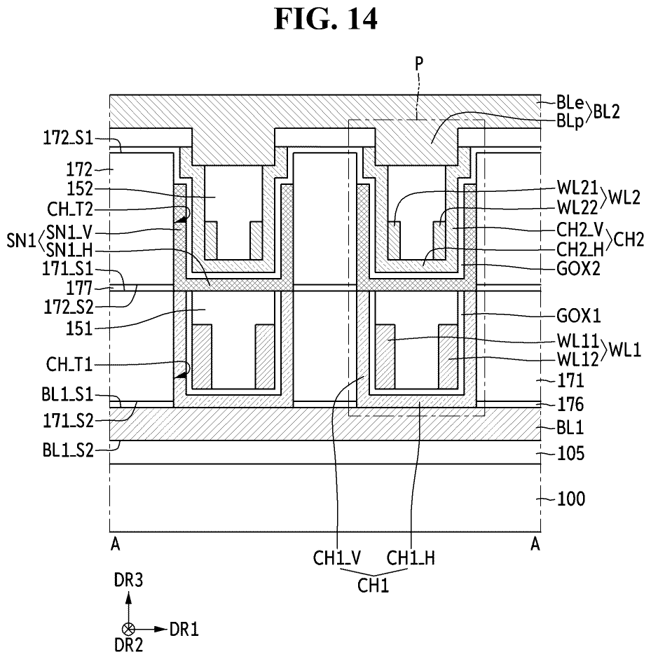

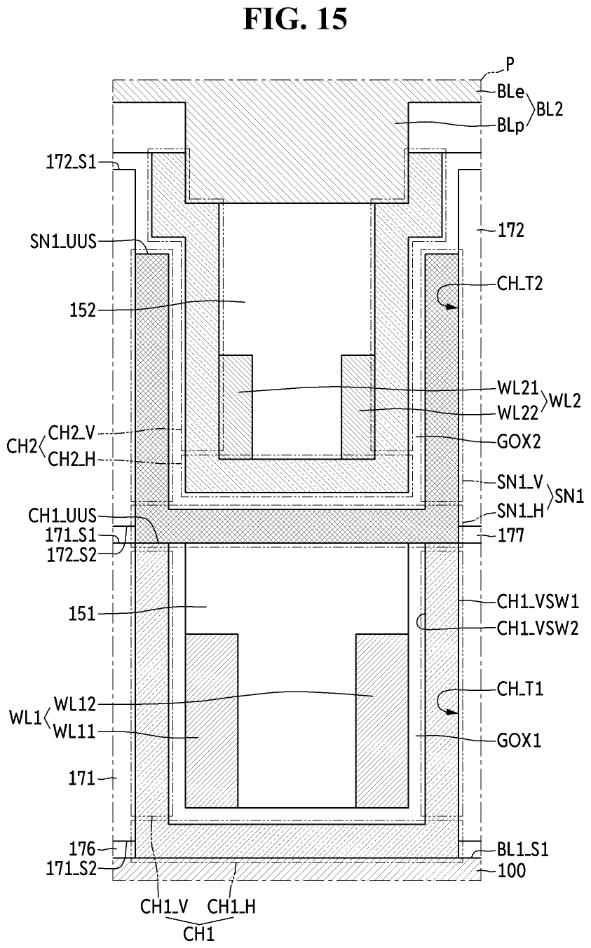

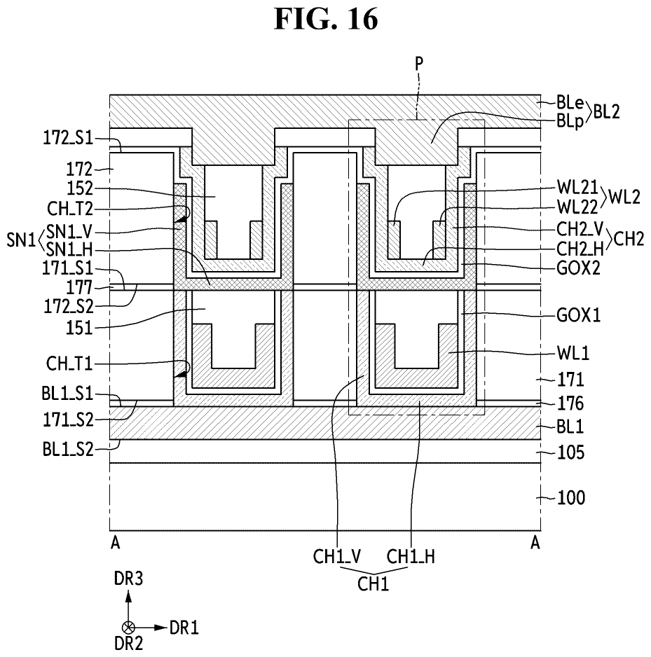

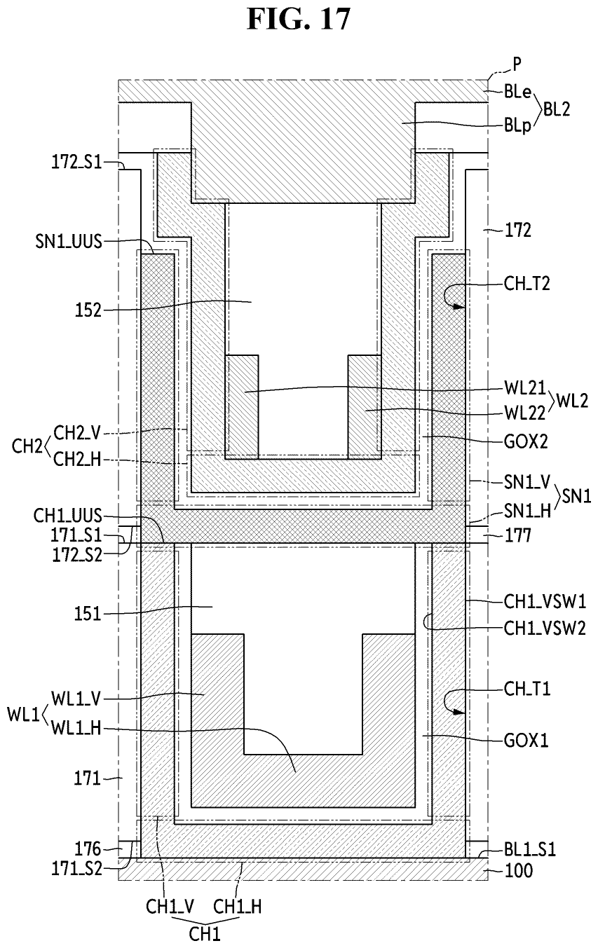

FIGS. 10 and 11 are views illustrating a semiconductor device according to some example embodiments. FIGS. 12 and 13 are views for describing a semiconductor device according to some example embodiments. FIGS. 14 and 15 are views illustrating a semiconductor device according to other example embodiments. FIGS. 16 and 17 are views illustrating a semiconductor device according to other example embodiments. For convenience of explanation, a description of elements that may be the same or substantially the same as those described previously may be omitted and contents different from those described previously with reference to FIGS. 2 to 9 will be mainly described in relation to the FIGS. 10 through 17.

Referring to FIGS. 10 to 13, in the semiconductor device according to some example embodiments, each first upper conductive line WL2 does not include two sub-conductive lines spaced apart from each other in the first direction DR1.

For example, each first upper conductive line WL2 may include one conductive line extending lengthwise in the second direction DR2.

In FIGS. 10 and 11, the first upper conductive line WL2 may have a shape similar to a rectangular shape in cross section.

In FIGS. 12 and 13, the first upper conductive line WL2 may include a horizontal portion WL2_H and vertical portions WL2_V. In cross section, the horizontal portion WL2_H of the first upper conductive line WL2 may extend in the first direction DR1. The vertical portion WL2_V of the first upper conductive line WL2 may protrude from the horizontal portion WL2_H of the first upper conductive line WL2 in the third direction DR3. The vertical portion WL2_V of the first upper conductive line WL2 may extend in the third direction DR3. The first upper conductive line WL2 may have a shape similar to a “U” shape in a cross section taken along the first direction DR1.

Referring to FIGS. 14 and 15, in the semiconductor device according to some example embodiments, the second lower conductive line WL1 may include a first lower sub-conductive line WL11 and a second lower sub-conductive line WL12.

Each of the first lower sub-conductive line WL11 and the second lower sub-conductive line WL12 may extend lengthwise in the second direction DR2. The first lower sub-conductive line WL11 and the second lower sub-conductive line WL12 may be spaced apart from each other in the first direction DR1. The first lower sub-conductive line WL11 and the second lower sub-conductive line WL12 may be electrically connected to each other. The first lower sub-conductive line WL11 and the second lower sub-conductive line WL12 may be spaced apart from each other in the first direction DR1, but may be electrically connected to one second lower contact plug WLPG1.

Referring to FIGS. 16 and 17, in the semiconductor device according to some example embodiments, the second lower conductive line WL1 may include a horizontal portion WL1_H and vertical portions WL1_V.

In cross section, the horizontal portion WL1_H of the second lower conductive line WL1 may extend in the first direction DR1. The vertical portion WL1_V of the second lower conductive line WL1 may protrude from the horizontal portion WL1_H of the second lower conductive line WL1 in the third direction DR3. The vertical portion WL1_V of the second lower conductive line WL1 may extend in the third direction DR3. The second lower conductive line WL1 may have a shape similar to a “U” shape in a cross section taken along the first direction DR1.

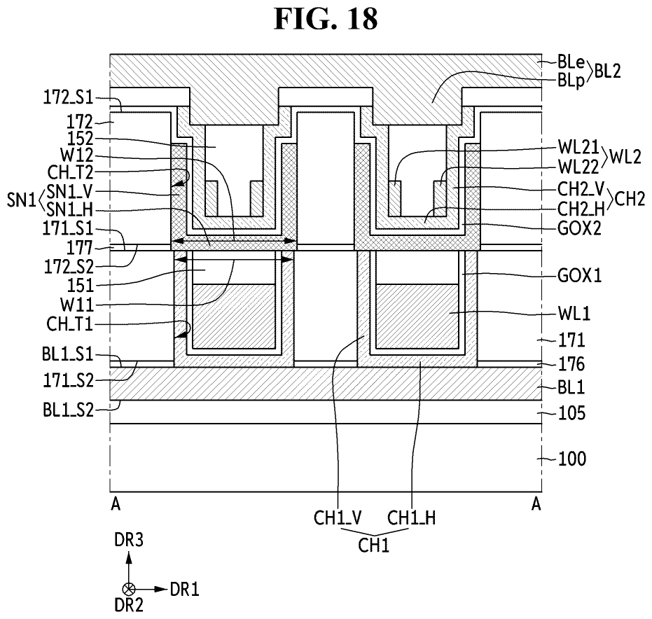

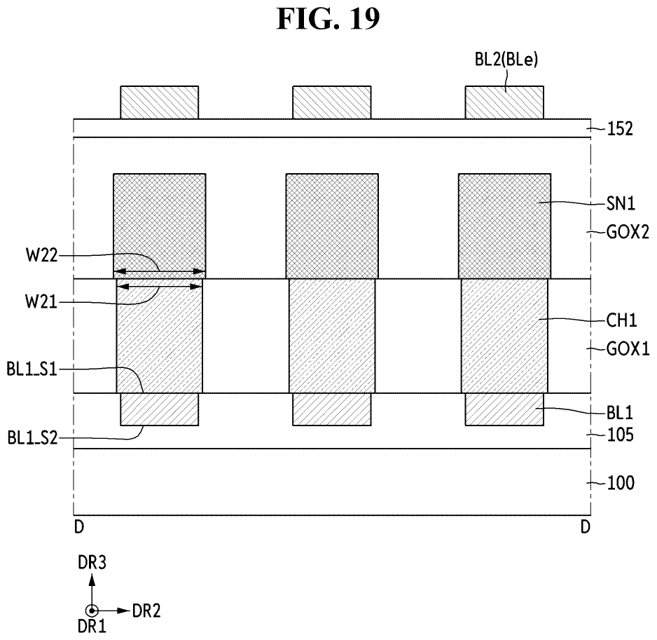

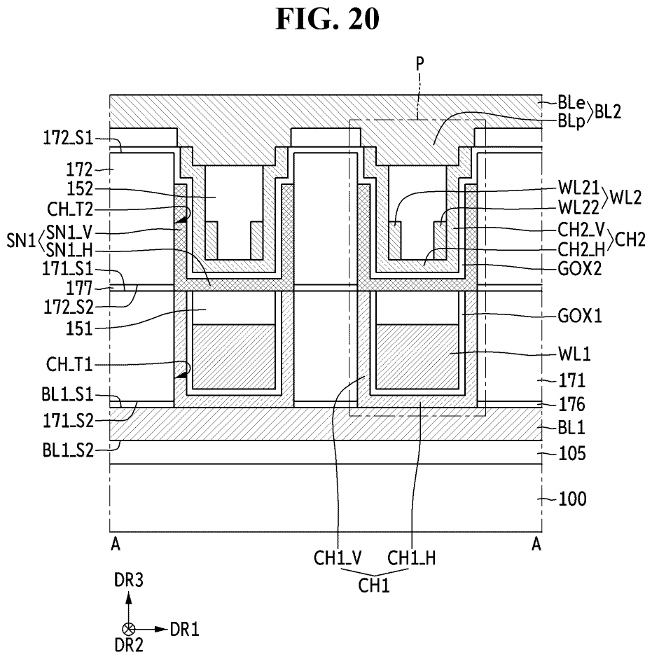

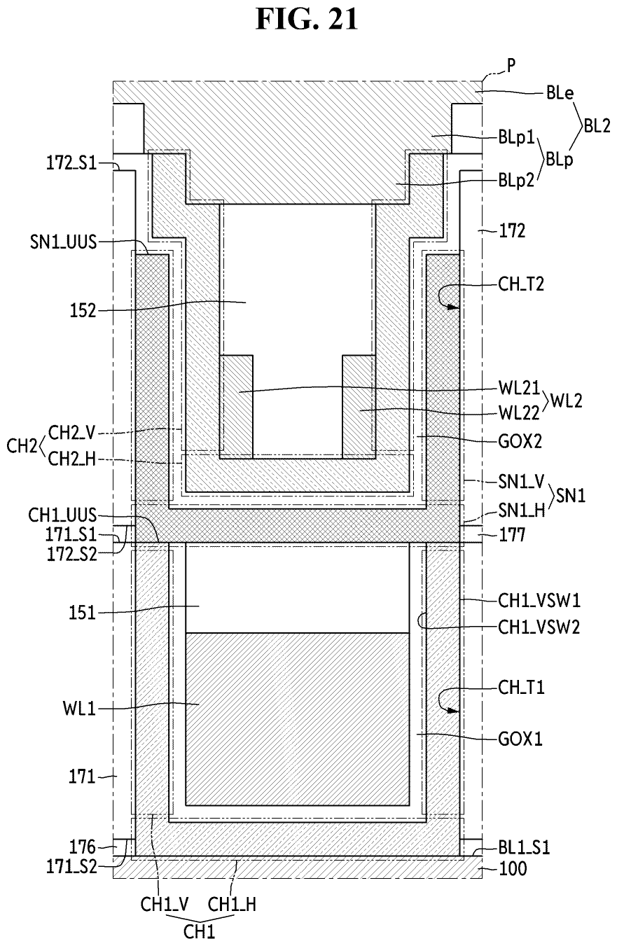

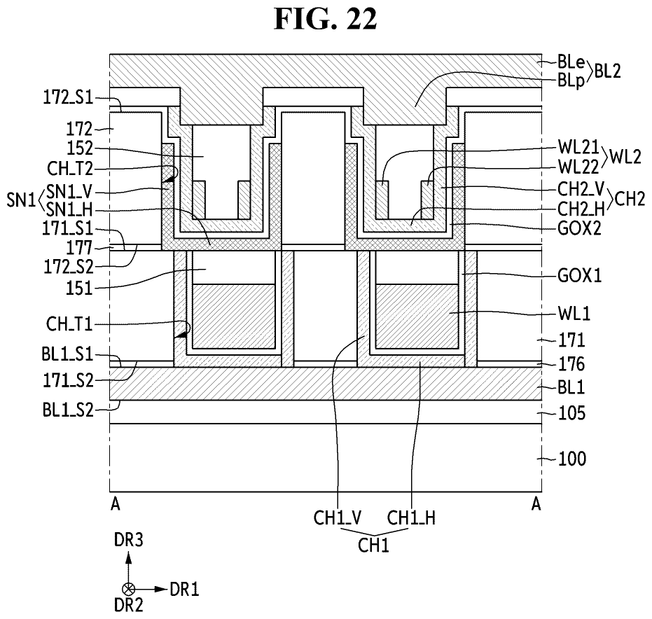

FIGS. 18 and 19 are views illustrating a semiconductor device according to some example embodiments. FIGS. 20 and 21 are views illustrating a semiconductor device according to some example embodiments. FIG. 22 is a view for describing a semiconductor device according to some example embodiments. For convenience of explanation, a description of elements that may be the same or substantially the same as those described previously may be omitted and contents different from those described with reference to FIGS. 2 to 9 will be mainly described.

Referring to FIGS. 18 and 19, in the semiconductor device according to some example embodiments, the width W12 of the first storage node pattern SN1 in the first direction DR1 may be greater than the width W11 of the first channel pattern CH1 in the first direction DR1.

The width W11 of the first channel trench CH_T1 in the first direction DR1 may be smaller than the width W12 of the second channel trench CH_T2 in the first direction DR1.

The width W22 of the first storage node pattern SN1 in the second direction DR2 may be greater than the width W21 of the first channel pattern CH1 in the second direction DR2.

Unlike the example illustrated, in some examples, the width W22 of the first storage node pattern SN1 in the second direction DR2 may be the same as the width W21 of the first channel pattern CH1 in the second direction DR2. As another example, the width W12 of the first storage node pattern SN1 in the first direction DR1 may be the same as the width W11 of the first channel pattern CH1 in the first direction DR1.

Referring to FIGS. 20 and 21, in the semiconductor device according to some example embodiments, the protrusion portion BLp of the second upper conductive line BL2 may include a first sub-protrusion portion BLp1 and a second sub-protrusion portion BLp2.

The first sub-protrusion portion BLp1 of the second upper conductive line BL2 may be disposed between the second sub-protrusion portion BLp2 of the second upper conductive line BL2 and the extension portion BLe of the second upper conductive line BL2. For example, in cross section, the second sub-protrusion portion BLp2 of the second upper conductive line BL2 may be disposed between the vertical portions CH2_V of the second channel pattern CH2 spaced apart from each other in the first direction DR1. The first sub-protrusion portion BLp1 of the second upper conductive line BL2 may be disposed on the second channel pattern CH2.

A width of the first sub-protrusion portion BLp1 of the second upper conductive line BL2 in the first direction DR1 may be greater than a width of the second sub-protrusion portion BLp2 of the second upper conductive line BL2 in the first direction DR1.

Referring to FIG. 22, in the semiconductor device according to some example embodiments, the first storage node pattern SN1 and the first channel pattern CH1 may be misaligned with each other in the third direction DR3.

For example, one sidewall of the first channel trench CH_T1 and one sidewall of the second channel trench CH_T2 may not be aligned with each other in the third direction DR3. The other sidewall of the first channel trench CH_T1 and the other sidewall of the second channel trench CH_T2 may not be aligned with each other in the third direction DR3.

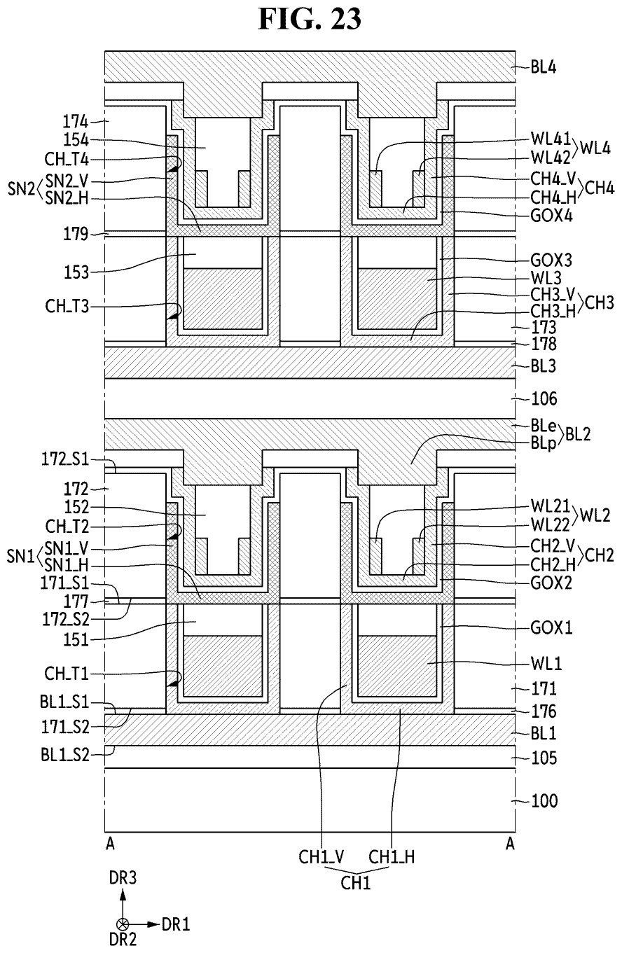

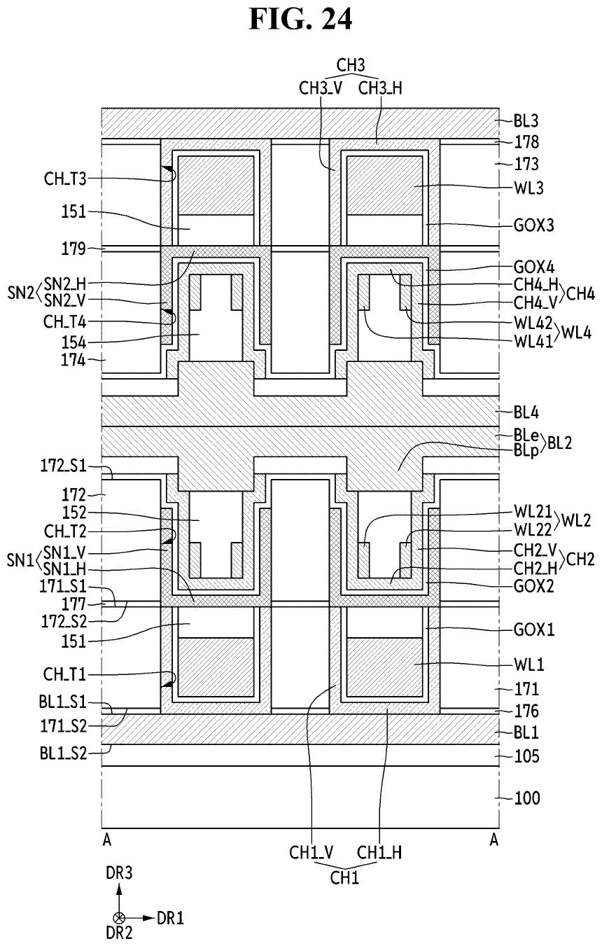

FIGS. 23 and 24 are views illustrating semiconductor devices according to some example embodiments, respectively. For convenience of explanation, a description of elements that may be the same or substantially the same as those described previously may be omitted and contents different from those described with reference to FIGS. 2 to 9 will be mainly described.

Referring to FIGS. 23 and 24, the semiconductor device according to some example embodiments may include a first memory structure ST1 and a second memory structure ST2 that are stacked in the third direction DR3.

The second memory structure ST2 may be disposed on the first memory structure ST1.

For example, the semiconductor device described above with reference to FIGS. 2 to 9 may constitute the first memory structure ST1, or in another example, the semiconductor device described with reference to FIGS. 10-22 may constitute the first memory structure ST1. In other words, the first memory structure ST1 may include a first lower conductive line BL1, a second lower conductive line WL1, a first upper conductive line WL2, a second upper conductive line BL2, a first channel pattern CH1, a second channel pattern CH2, and a first storage node pattern SN1.

Hereinafter, the second memory structure ST2 will be mainly described.

The second memory structure ST2 may include a third lower conductive line BL3, a fourth lower conductive line WL3, a third upper conductive line WL4, a fourth upper conductive line BL4, a third channel pattern CH3, a fourth channel pattern CH4, and a second storage node pattern SN2. The third upper conductive line WL4 may include a third upper sub-conductive line WL41 and a fourth upper sub-conductive line WL42 spaced apart from each other in the first direction DR1.

A description of the third lower conductive line BL3, the fourth lower conductive line WL3, the third upper conductive line WL4, the fourth upper conductive line BL4, the third channel pattern CH3, the fourth channel pattern CH4, and the second storage node pattern SN2 that are included in the second memory structure ST2 may be substantially the same as the description of the first lower conductive line BL1, the second lower conductive line WL1, the first upper conductive line WL2, the second upper conductive line BL2, the first channel pattern CH1, the second channel pattern CH2, and the first storage node pattern SN1 that are included in the first memory structure ST1.

The third channel pattern CH3 may include a horizontal portion CH3_H and vertical portions CH3_V. The fourth channel pattern CH4 may include a horizontal portion CH4_H and vertical portions CH4_V. The second storage node pattern SN2 may include a horizontal portion SN2_H and vertical portions SN2_V.

A third protrusion insulating pattern 173 may be disposed on the third lower conductive line BL3. A third etch stop film 178 may be disposed between the third protrusion insulating pattern 173 and the third lower conductive line BL3. The third protrusion insulating pattern 173 may include a plurality of third channel trenches CH_T3. Each third channel trench CH_T3 may extend to be elongated in the second direction DR2.

A second lower gate insulating pattern GOX3 may be disposed between the third channel pattern CH3 and the fourth lower conductive line WL3. The second lower gate insulating pattern GOX3 may be disposed between the third channel pattern CH3 and the second storage node pattern SN2. The second lower gate insulating pattern GOX3 may extend along an inner profile of the third channel pattern CH3.

The third channel pattern CH3 and the fourth lower conductive line WL3 may be disposed in the third channel trench CH_T3. A second lower isolation insulating pattern 153 may be disposed on the second lower gate insulating pattern GOX3. The second lower isolation insulating pattern 153 may fill the third channel trench CH_T3 remaining after the third channel pattern CH3, the second lower gate insulating pattern GOX3, and the fourth lower conductive line WL3 are formed.

A fourth protrusion insulating pattern 174 may be disposed on the third protrusion insulating pattern 173. A fourth etch stop film 179 may be disposed between the third protrusion insulating pattern 173 and the fourth protrusion insulating pattern 174. The fourth protrusion insulating pattern 174 may include a plurality of fourth channel trenches CH_T4. Each fourth channel trench CH_T4 may extend to be elongated in the second direction DR2.

A second upper gate insulating pattern GOX4 may be disposed between the fourth channel pattern CH4 and the second storage node pattern SN2. The second upper gate insulating pattern GOX4 may extend along an inner profile of the second storage node pattern SN2. The second upper gate insulating pattern GOX4 may extend along a portion of a sidewall of the fourth channel trench CH_T4.

The second storage node pattern SN2, the fourth channel pattern CH4, and the third upper conductive line WL4 may be disposed in the fourth channel trench CH_T4. A second upper isolation insulating pattern 154 may be disposed on the fourth channel pattern CH4. At least a portion of the second upper isolation insulating pattern 154 may be disposed in the fourth channel trench CH_T4.

For example, the third lower conductive line BL3 may correspond to the write bit line WBL of the write transistor WTR of FIG. 1. The fourth lower conductive line WL3 may correspond to the write word line WWL of the write transistor WTR of FIG. 1. The second storage node pattern SN2 may be a portion corresponding to the storage node SN of FIG. 1.

As an example, the third upper conductive line WL4 may correspond to the read word line RWL of the read transistor RTR of FIG. 3. The fourth upper conductive line BL4 may correspond to the read bit line RBL of the read transistor RTR. As another example, the third upper conductive line WL4 may correspond to the read bit line RBL of the read transistor RTR of FIG. 3. The fourth upper conductive line BL4 may correspond to the read word line RWL of the read transistor RTR.

Unlike the example illustrated, in some examples a shape of the third upper conductive line WL4 may be similar to the shape of the first upper conductive line WL2 illustrated in FIGS. 10 and 12.

Unlike the example illustrated, in some examples a shape of the fourth lower conductive line WL3 may be similar to the shape of the second lower conductive line WL1 illustrated in FIGS. 14 and 16.

In FIG. 23, the third lower conductive line BL3 may be disposed between the second upper conductive line BL2 and the fourth lower conductive line WL3. An insertion insulating film 106 may be disposed between the third lower conductive line BL3 and the second upper conductive line BL2. The insertion insulating film 106 includes an insulating material.

The second memory structure ST2 may be formed on the substrate 100 on which the first memory structure ST1 is formed.

In FIG. 24, the fourth upper conductive line BL4 may be bonded to the second upper conductive line BL2.

The second memory structure ST2 including the third lower conductive line BL3, the fourth lower conductive line WL3, the third upper conductive line WL4, the fourth upper conductive line BL4, the third channel pattern CH3, the fourth channel pattern CH4, and the second storage node pattern SN2 may be sequentially formed on a supporting substrate. The supporting substrate including the second memory structure ST2 may be bonded to the substrate 100. Thereafter, the supporting substrate may be removed. The bonding between the supporting substrate and the substrate 100 may be performed using, for example, the fourth upper conductive line BL4 and the second upper conductive line BL2.

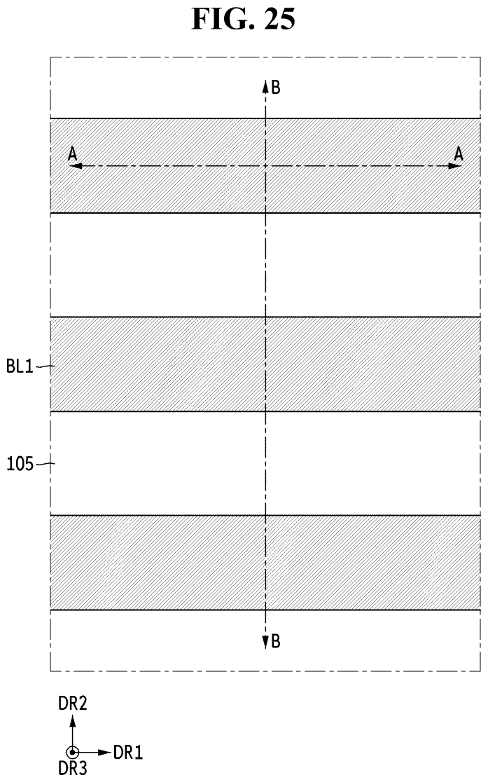

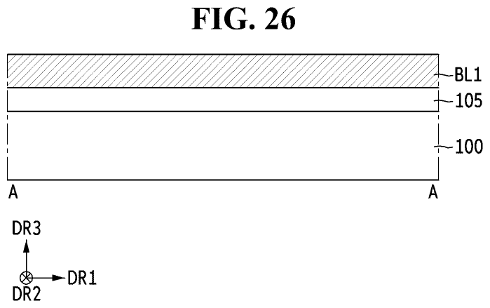

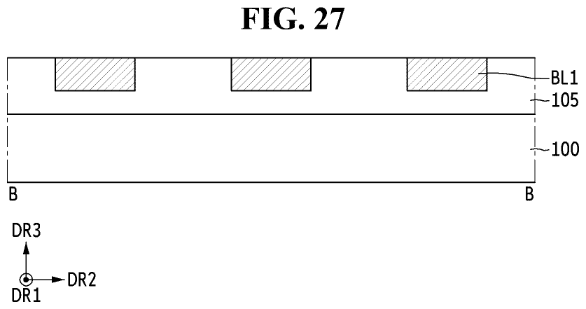

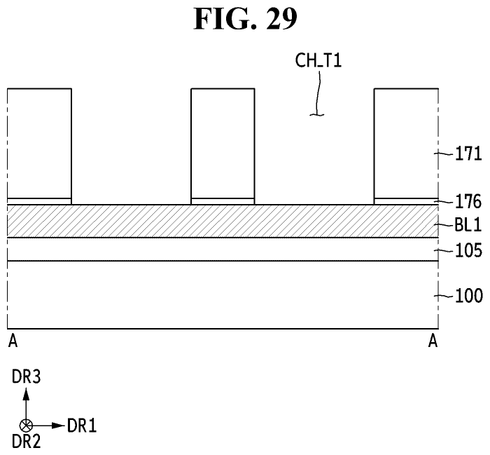

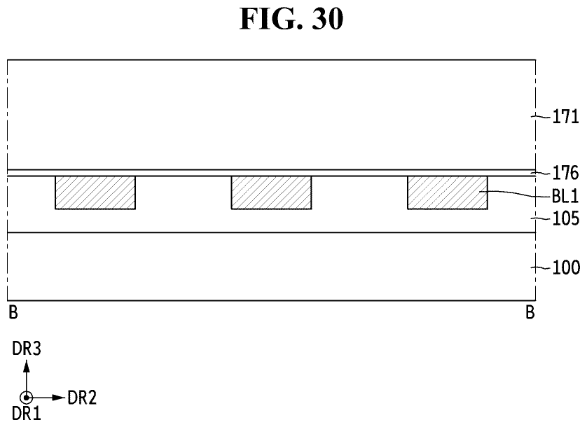

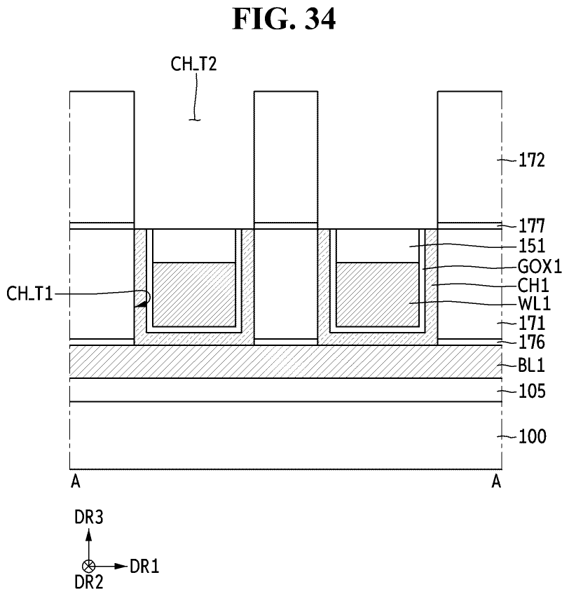

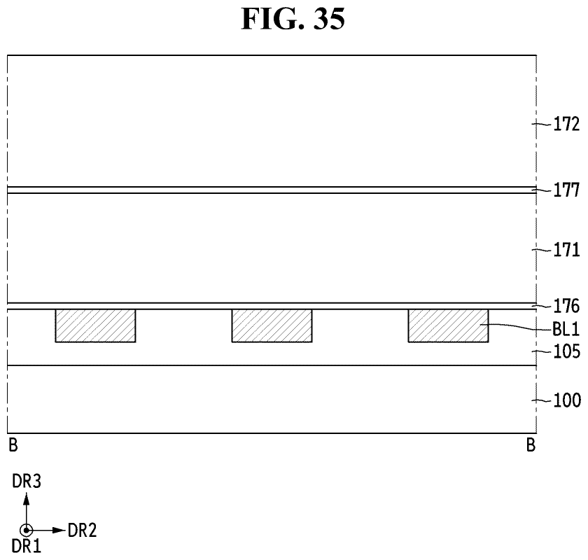

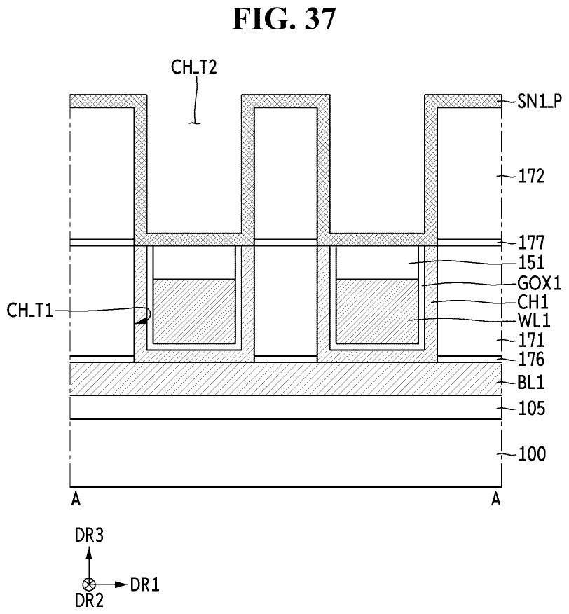

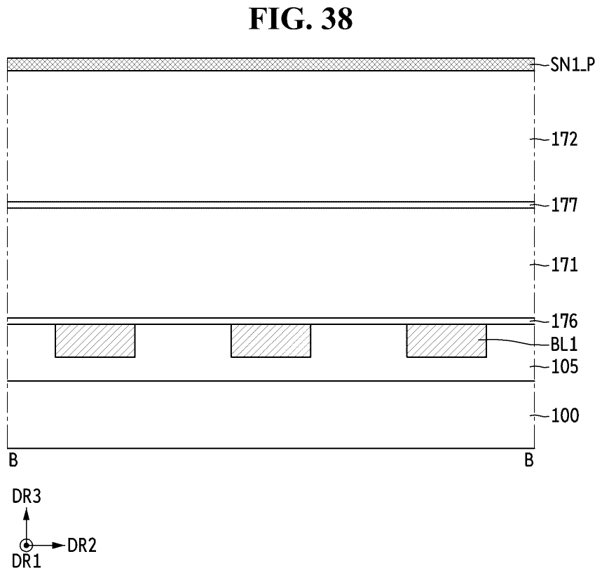

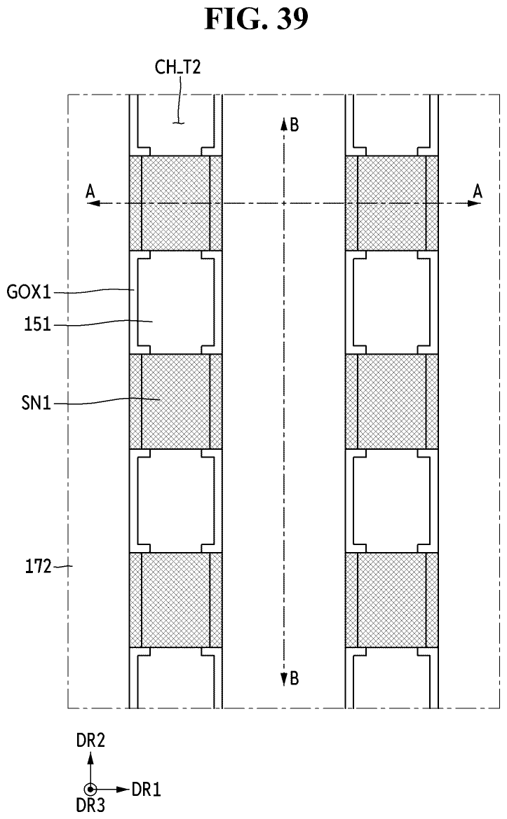

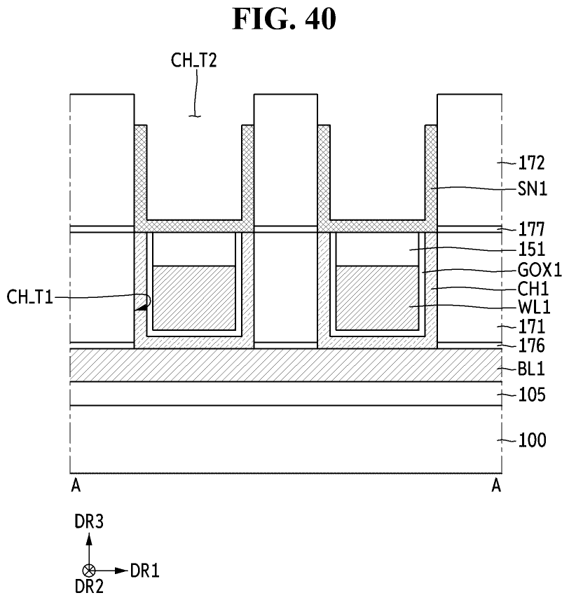

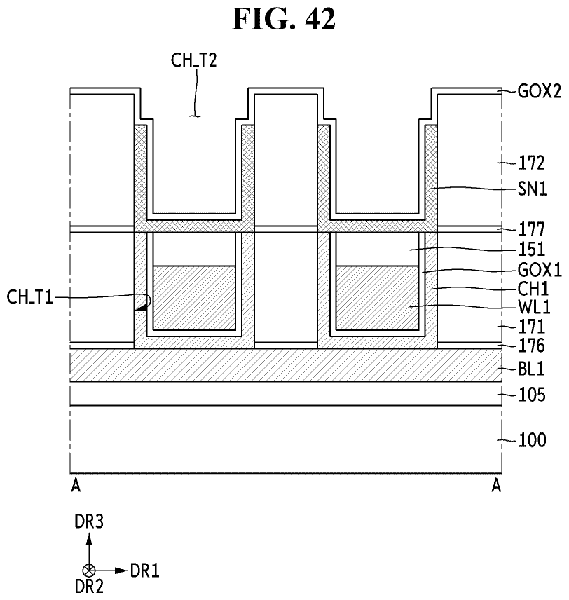

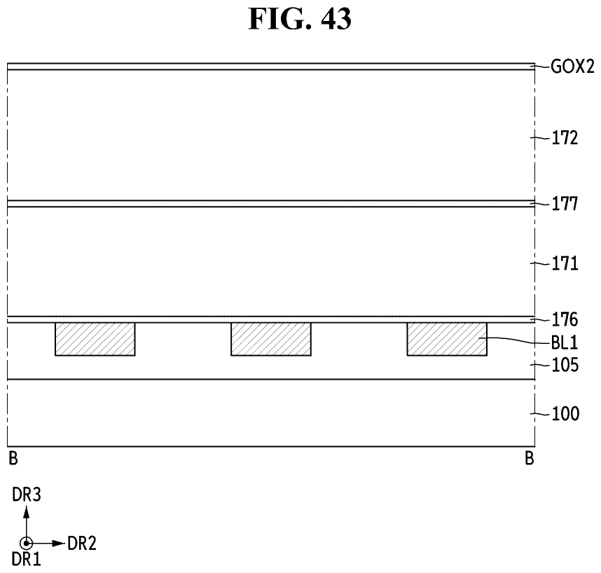

FIGS. 25 to 48 are views of intermediate steps illustrating a semiconductor device according to some example embodiments. For simplicity of explanation, contents overlapping the above-described contents will be briefly described or a description thereof will be omitted.

Referring to FIGS. 25 to 27, a first lower conductive line BL1 may be formed on a substrate 100.

As an example, a first portion of a lower insulating film 105 may be formed on the substrate 100. A lower conductive line film may be formed on the first portion of the lower insulating film 105. The first lower conductive line BL1 may be formed by patterning the lower conductive line film. Subsequently, a second portion of the lower insulating film 105 may be formed between the first lower conductive lines BL1 adjacent to each other in the second direction DR2. Through this, the lower insulating film 105 may be formed.

As another example, a lower insulating film 105 may be formed on a substrate 100. A lower conductive line trench may be formed in the lower insulating film 105. Subsequently, the first lower conductive line BL1 filling the lower conductive line trench may be formed.

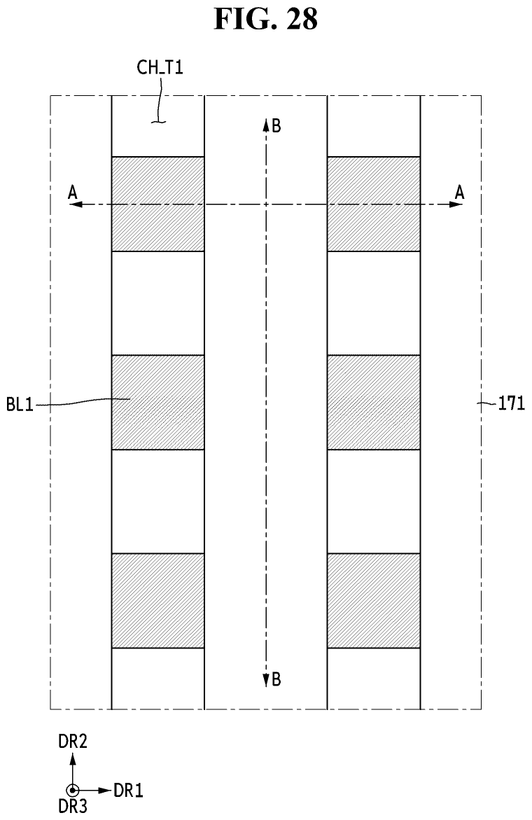

Referring to FIGS. 28 to 30, a first protrusion insulating pattern 171 may be formed on the first lower conductive line BL1 and the lower insulating film 105.

The first protrusion insulating pattern 171 may include a plurality of first channel trenches CH_T1 exposing the first lower conductive line BL1.

More specifically, a protrusion insulating film may be formed on the first lower conductive line BL1. The first channel trench CH_T1 may be formed in the protrusion insulating film. Through this, the first protrusion insulating pattern 171 may be formed.

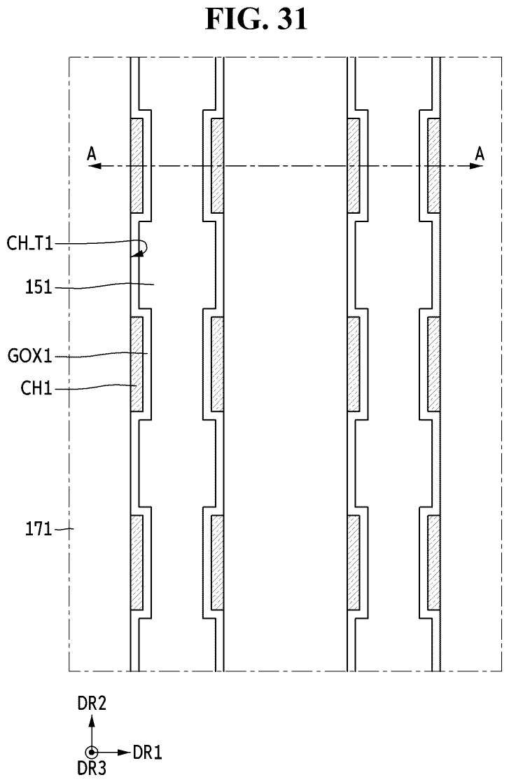

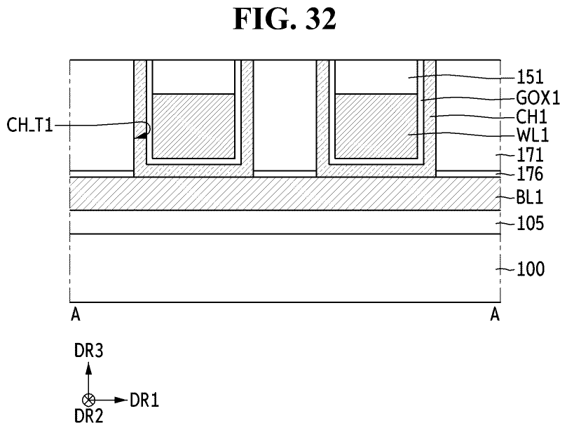

Referring to FIGS. 31 and 32, first channel patterns CH1 may be formed on the first lower conductive line BL1.

The first channel patterns CH1 may be formed in the first channel trench CH_T1. For example, a channel pattern film may be formed along sidewalls and a bottom surface of the first channel trench CH_T1. The channel pattern film may be formed along an upper surface of the first protrusion insulating pattern 171. A pre-channel film may be patterned using a photo process. Through this, the first channel patterns CH1 may be formed.

Subsequently, a first lower gate insulating pattern GOX1 may be formed on the first channel patterns CH1. The first lower gate insulating pattern GOX1 may be formed along the sidewalls and bottom surface of the first channel trench CH_T1 and the upper surface of the first protrusion insulating pattern 171.

A second lower conductive line WL1 may be formed on the first lower gate insulating pattern GOX1. The second lower conductive line WL1 may be formed in the first channel trench CH_T1. As illustrated in FIG. 14 or FIG. 16, a cross-sectional shape of the second lower conductive line WL1 may be changed depending on a method of forming the second lower conductive line WL1.

A first lower isolation insulating pattern 151 may be formed on the second lower conductive line WL1. The first lower isolation insulating pattern 151 may fill the first channel trench CH_T1. While the first lower isolation insulating pattern 151 is formed, the first lower gate insulating pattern GOX1 on the upper surface of the first protrusion insulating pattern 171 may be removed. The uppermost surface of the first channel pattern CH1 may be exposed.

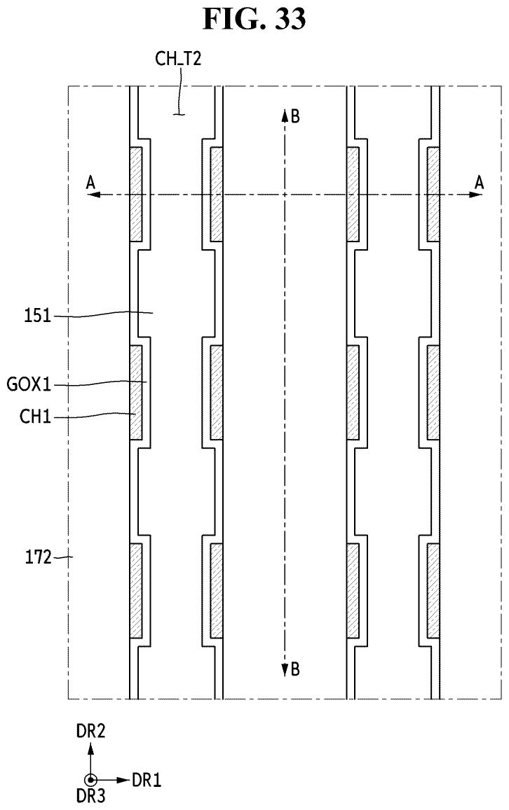

Referring to FIGS. 33 to 35, a second protrusion insulating pattern 172 may be formed on the first protrusion insulating pattern 171, the first channel pattern CH1, and the second lower conductive line WL1.

The second protrusion insulating pattern 172 may include a plurality of second channel trenches CH_T2 exposing the first lower isolation insulating pattern 151 and the first channel pattern CH1.

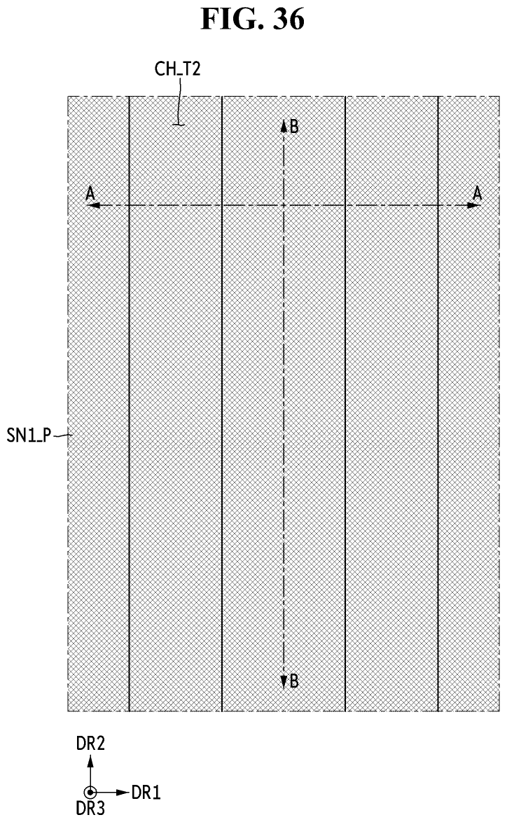

Referring to FIGS. 36 to 38, a pre-storage node film SN1_P may be formed on the first lower isolation insulating pattern 151 and the first channel pattern CH1.

The pre-storage node film SN1_P may be formed along sidewalls and bottom surface of the second channel trench CH_T2. The pre-storage node film SN1_P may be formed along an upper surface of the second protrusion insulating pattern 172.

Referring to FIGS. 36 to 40, first storage node patterns SN1 may be formed by patterning the pre-storage node film SN1_P.

Each first storage node pattern SN1 may be formed on the corresponding first channel pattern CH1.

More specifically, a first sacrificial pattern filling a portion of the second channel trench CH_T2 may be formed. The first sacrificial pattern may not cover a portion of the sidewall of the second channel trench CH_T2. In other words, after the first sacrificial pattern is formed, a portion of the pre-storage node film SN1_P on the sidewall of the second channel trench CH_T2 and the pre-storage node film SN1_P on the upper surface of the second protrusion insulating pattern 172 may be exposed. The pre-storage node film SN1_P on the upper surface of the second protrusion insulating pattern 172 may be removed using the first sacrificial pattern as a mask. In addition, a portion of the pre-storage node film SN1_P on the sidewall of the second channel trench CH_T2 may be removed using the first sacrificial pattern as a mask. As a result, a pre-storage node pattern may be formed in the second channel trench CH_T2. The uppermost surface of the pre-storage node pattern is lower than the uppermost surface of the second protrusion insulating pattern 172.

Subsequently, a second sacrificial pattern may be formed on the pre-storage node pattern. The pre-storage node pattern may be patterned using the second sacrificial pattern as a mask. As a result, the first storage node patterns SN1 arranged in the first direction DR1 and the second direction DR2 may be formed.

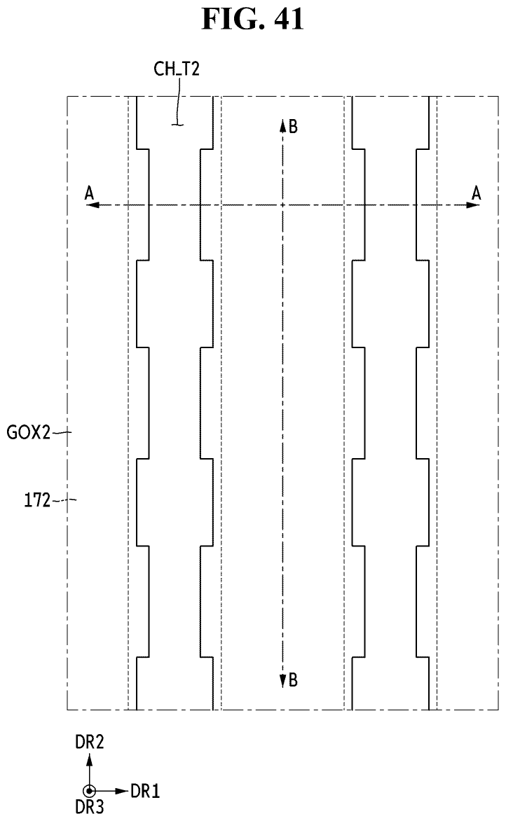

Referring to FIGS. 41 to 43, a first upper gate insulating pattern GOX2 may be formed on the first storage node patterns SN1.

The first upper gate insulating pattern GOX2 may be formed along the sidewall and bottom surface of the second channel trench CH_T2 and the upper surface of the second protrusion insulating pattern 172.

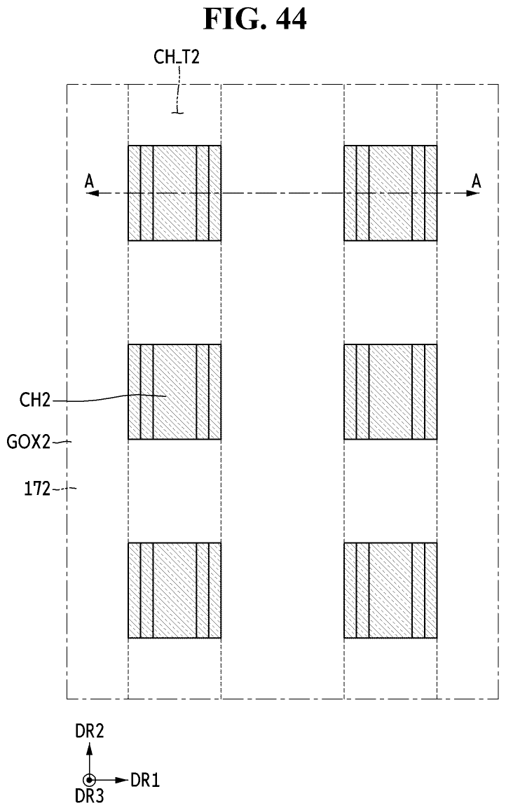

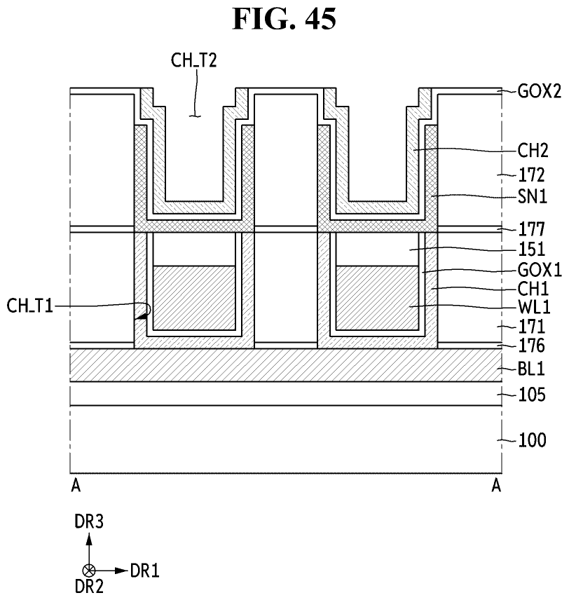

Referring to FIGS. 44 and 45, second channel patterns CH2 may be formed on the first upper gate insulating pattern GOX2.

The second channel patterns CH2 may be formed in the second channel trench CH_T2.

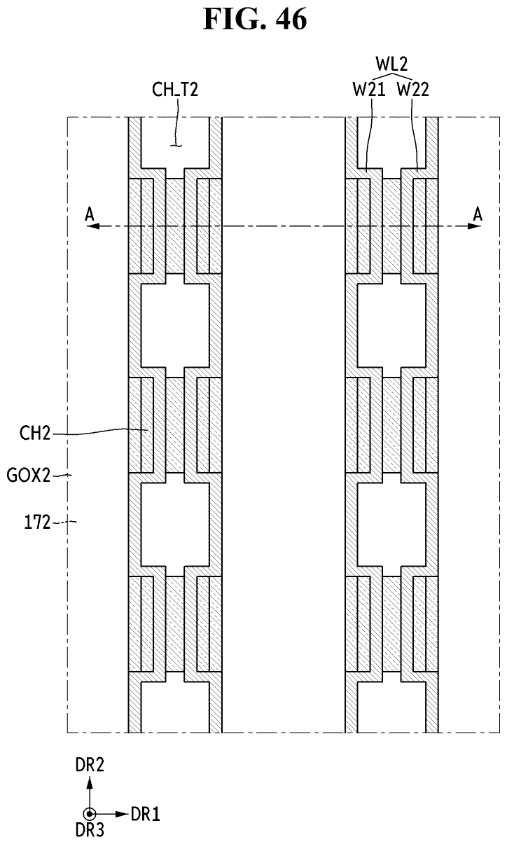

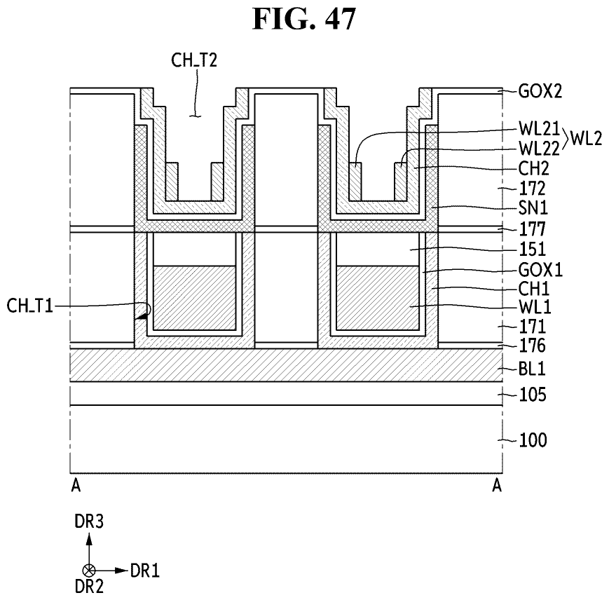

Referring to FIGS. 46 and 47, a first upper conductive line WL2 may be formed on the second channel pattern CH2 and the first upper gate insulating pattern GOX2.

The first upper conductive line WL2 may be formed in the second channel trench CH_T2. As illustrated in FIG. 10 or FIG. 12, a cross-sectional shape of the first upper conductive line WL2 may be changed depending on a method of forming the first upper conductive line WL2.

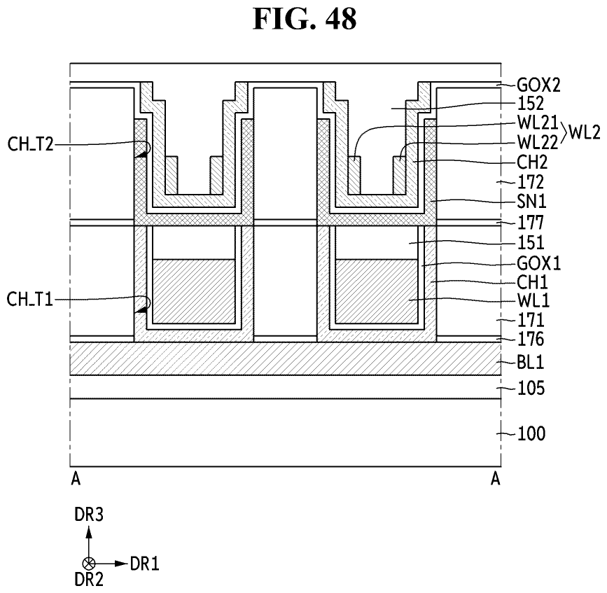

Referring to FIG. 48, a first upper isolation insulating pattern 152 may be formed on the first upper conductive line WL2, the second channel pattern CH2, and the first upper gate insulating pattern GOX2.

The first upper isolation insulating pattern 152 may fill the second channel trench CH_T2. The first upper isolation insulating pattern 152 may be formed on the upper surface of the second protrusion insulating pattern 172. Unlike illustrated, the first upper isolation insulating pattern 152 may not be formed on the upper surface of the second protrusion insulating pattern 172.

Subsequently, referring to FIGS. 4 to 7, a second upper conductive pattern BL2 may be formed on the second channel pattern CH2.

As an example, a contact hole exposing the second channel pattern CH2 may be formed in the first upper isolation insulating pattern 152. An upper conductive line film may be formed on the first upper isolation insulating pattern 152. The upper conductive line film may fill the contact hole exposing the second channel pattern CH2. Subsequently, the second upper conductive line BL2 may be formed by patterning the upper conductive line film.

As another example, an upper conductive line trench may be formed in the first upper isolation insulating pattern 152. The upper conductive line trench may expose the second channel pattern CH2. Subsequently, the second upper conductive line BL2 filling the upper conductive line trench may be formed.

In concluding the detailed description, those skilled in the art will appreciate that many variations and modifications may be made to the disclosed embodiments without substantially departing from the principles of the inventive concept. Therefore, the disclosed embodiments of the disclosure are generic and are for descriptive sense only and not for purposes of limitation.

What is claimed is:

1. A semiconductor device comprising:
a first lower conductive line extending lengthwise in a first direction and including a first surface and a second surface opposing each other in a second direction;
a first channel pattern disposed on the first surface of the first lower conductive line and connected to the first lower conductive line;
a storage node pattern disposed on the first channel pattern and in contact with the first channel pattern;
a second lower conductive line extending lengthwise in a third direction, overlapping the storage node pattern in the second direction, and disposed between the storage node pattern and the first channel pattern;
a first upper conductive line disposed on the storage node pattern, extending lengthwise in the third direction, and overlapping the second lower conductive line in the second direction;
a second channel pattern disposed between the first upper conductive line and the storage node pattern and connected to the first upper conductive line;
an upper gate insulating pattern disposed between the second channel pattern and the storage node pattern; and
a second upper conductive line extending lengthwise in the first direction, disposed on the second channel pattern, and connected to the second channel pattern,
wherein a width of the storage node pattern in the first direction is greater than a width of the second lower conductive line in the first direction.

2. The semiconductor device of claim 1, wherein the storage node pattern includes a horizontal portion extending in the first direction and a vertical portion extending in the second direction, and the first channel pattern is in contact with the horizontal portion of the storage node pattern.

3. The semiconductor device of claim 1, wherein the first channel pattern includes a horizontal portion extending in the first direction and a vertical portion extending in the second direction, and the first surface of the first lower conductive line is connected to the horizontal portion of the first channel pattern.

4. The semiconductor device of claim 1, wherein the second channel pattern includes a horizontal portion extending in the first direction and a vertical portion extending in the second direction.

5. The semiconductor device of claim 1, wherein the width of the storage node pattern in the first direction is the same as or greater than a width of the first channel pattern in the first direction.

6. The semiconductor device of claim 1, wherein a width of the storage node pattern in the third direction is the same as or greater than a width of the first channel pattern in the third direction.

7. The semiconductor device of claim 1, further comprising a lower gate insulating pattern disposed between the first channel pattern and the second lower conductive line.

8. The semiconductor device of claim 7, wherein the lower gate insulating pattern is in contact with the storage node pattern.

9. The semiconductor device of claim 1, wherein each of the first channel pattern and the second channel pattern includes a metal oxide semiconductor material.

10. The semiconductor device of claim 1, wherein the first upper conductive line includes a first sub-conductive line and a second sub-conductive line spaced apart from each other in the first direction.

11. The semiconductor device of claim 1, wherein the first upper conductive line includes a horizontal portion extending in the first direction and a vertical portion protruding in the second direction.

12. A semiconductor device comprising:
a first lower conductive line extending lengthwise in a first direction and including a first surface and a second surface opposing each other in a second direction;
a lower protrusion insulating pattern disposed on the first surface of the first lower conductive line and including a lower channel trench extending in a third direction;
a first channel pattern extending along the first surface of the first lower conductive line and a sidewall of the lower channel trench and connected to the first lower conductive line;
a second lower conductive line disposed on the first channel pattern in the lower channel trench and extending lengthwise in the third direction;
an upper protrusion insulating pattern disposed on the lower protrusion insulating pattern and including an upper channel trench extending in the third direction;
a second channel pattern including a horizontal portion extending in the first direction and a vertical portion disposed on a sidewall of the upper channel trench, and overlapping the first channel pattern in the second direction;
a storage node pattern disposed between the first channel pattern and the second channel pattern in the upper channel trench and in contact with the first channel pattern;
a first upper conductive line disposed on the second channel pattern and connected to the second channel pattern;
an upper gate insulating pattern disposed between the second channel pattern and the storage node pattern; and
a second upper conductive line extending lengthwise in the first direction, disposed on the second channel pattern, and connected to the second channel pattern.

13. The semiconductor device of claim 12, wherein:
the storage node pattern includes a horizontal portion extending in the first direction and a vertical portion extending along a portion of the sidewall of the upper channel trench, and
the first channel pattern is in contact with the horizontal portion of the storage node pattern.

14. The semiconductor device of claim 12, wherein a width of the upper channel trench in the first direction is the same as or greater than a width of the lower channel trench in the first direction.

15. The semiconductor device of claim 12, wherein a width of the storage node pattern in the third direction is the same as or greater than a width of the first channel pattern in the third direction.

16. The semiconductor device of claim 12, wherein:
the first channel pattern includes a horizontal portion extending along the first surface of the first lower conductive line and a vertical portion extending along the sidewall of the lower channel trench,
the vertical portion of the first channel pattern includes a first sidewall and a second sidewall opposing each other in the first direction, and
the second lower conductive line is disposed on the first sidewall of the vertical portion of the first channel pattern, and is not disposed on the second sidewall of the vertical portion of the first channel pattern.

17. The semiconductor device of claim 12, further comprising a lower gate insulating pattern disposed between the first channel pattern and the second lower conductive line,
wherein the lower gate insulating pattern extends along a profile of the first channel pattern.

18. The semiconductor device of claim 12, wherein the upper gate insulating pattern extends along an upper surface of the upper protrusion insulating pattern.

19. A semiconductor device comprising:
a first lower conductive line extending lengthwise in a first direction and including a first surface and a second surface opposing each other in a second direction;
a second lower conductive line disposed on the first surface of the first lower conductive line and extending lengthwise in a third direction;
a first channel pattern disposed between the first lower conductive line and the second lower conductive line and connected to the first lower conductive line, a width of the first channel pattern in the first direction being greater than a width of the second lower conductive line in the first direction;
a lower gate insulating pattern disposed between the first channel pattern and the second lower conductive line;
a storage node pattern disposed on the first channel pattern and the lower gate insulating pattern and including a horizontal portion extending in the first direction and vertical portions extending in the second direction, the horizontal portion of the storage node pattern being in contact with the first channel pattern, and a width of the storage node pattern in the first direction being greater than the width of the second lower conductive line in the first direction;
a first upper conductive line disposed between the vertical portions of the storage node pattern spaced apart from each other in the first direction, extending lengthwise in the third direction, and overlapping the second lower conductive line in the second direction;
a second channel pattern disposed between the first upper conductive line and the storage node pattern and connected to the first upper conductive line;
an upper gate insulating pattern disposed between the second channel pattern and the storage node pattern; and
a second upper conductive line extending lengthwise in the first direction, disposed on the second channel pattern, and connected to the second channel pattern.

20. The semiconductor device of claim 19, wherein in cross section, each of the first channel pattern and the storage node pattern has a U-shape.
